(19) United States
(12) Patent Application Publication
(10) Pub. No.: US 2016/0236345 A1
(43) Pub. Date: Aug. 18, 2016

(54) TRANSFER DEVICE AND VACUUM APPARATUS

(71) Applicant: ULVAC KIKO, Inc., Saito City (JP)

(72) Inventor: Takahiro YOSHINO, Chigasaki-shi (JP)

(73) Assignee: ULVAC KIKO, Inc., Saito City (JP)

(21) Appl. No.: 15/140,575

(22) Filed: Apr. 28, 2016

Related U.S. Application Data
(63) Continuation of application No. PCT/JP2015/075013, filed on Sep. 2, 2015.

(30) Foreign Application Priority Data
Sep. 3, 2014 (JP) 2014-178675

(51) Int. Cl. B25J 9/06; H01L 21/677

(52) U.S. Cl. CPC B25J 9/06; H01L 21/67742

(57) ABSTRACT

The present invention provides a system that facilitates positioning operations and also improves throughput in transferring a substrate in a transfer device that can transfer a pair of transfer objects simultaneously. The present invention includes first and second extension/contraction drive shafts disposed concentrically with a rotating axis as a center, each provided in an independently rotatable manner in a horizontal plane, and first and second turning drive shafts. First and second transfer mechanisms are disposed on both sides of a transfer object transfer direction with the rotating axis being disposed therebetween, are driven to extend and contract by the first and second extension/contraction drive shafts, and transfer a transfer object along the transfer object transfer direction. The first and second transfer mechanisms are configured to turn at a small angle with the rotating axis as a center by first and second turning drive members.

### TECHNICAL FIELD

The present invention generally relates to a transfer device that transfers a transfer object (such as, a substrate), and more particularly relates to a technique concerning a transfer device suitable for a vacuum apparatus (for example, in a semiconductor manufacturing device).

### BACKGROUND ART

FIGS. 17 and 18 are diagrams for explaining problems in the conventional techniques.

Conventionally, as illustrated in FIG. 17(a), there have been known a vacuum apparatus that has a transfer chamber having a quadrilateral shape, each side of which has two processing chambers.

For example, as illustrated in FIG. 17(a), this vacuum processing device 101 includes pairs of processing chambers 102 and 103, 104 and 105, and 108 and 109 (reference numerals 106 and 107 represent a loading and unloading chamber, respectively) provided at each side around the transfer chamber 100.

Meanwhile, with this kind of transfer apparatus, a transfer device 120 that has a pair of substrate mounting units 121 and 122 to improve throughput in transferring substrates is known.

However, in such a conventional system, in many instances, the distance, for example, between the processing chambers 102 and 103 (in other words, the distance between substrates 110 and 111) may not be equal to the distance between the substrate mounting units 121 and 122 of the transfer device 120, and there is a problem that positioning operations are difficult.

Furthermore, in the case where the distance between the substrate 110, 111 and the substrate mounting unit 121, 122 of the transfer device 120 is large, two substrates 110 and 111 cannot be placed on the substrate mounting units 121 and 122 of the transfer device 120 simultaneously as illustrated in, for example, FIG. 17(b).

In such a case, it has also been done that the transfer device 120 is turned to angle the substrate mounting units 121 and 122 as illustrated in, for example, FIGS. 18 (a) and 18(b), so that two substrates 110 and 111 are placed on the substrate mounting units 121 and 122 one by one, respectively.

However, there is a problem with such a conventional system because such an operation degrades throughput.

### RELATED ART DOCUMENTS

### Patent Document

Patent Literature 1: Japanese Patent Application Laid-Open Publication No. 2013-084823

### DISCLOSURE OF THE INVENTION

### Problems to be Solved by the Invention

The present invention has been made to solve the problems in the conventional system as described above; and an object of the present invention is to provide a system that facilitates positioning operations and also improves throughput in transferring substrates in a transfer device that can transfer a pair of transfer objects simultaneously.

### Means for Solving the Problems

The present invention that has been made to achieve the object described above is a transfer device including first and second extension/contraction drive shafts for driving extension and contraction of first and second transfer mechanisms, the first and second extension/contraction drive shafts being disposed concentrically about a predetermined rotating axis as a center and each provided in an independently rotatable manner in a horizontal plane; and first and second turning drive shafts for turning the first and second transfer mechanisms, the first and second turning drive shafts being disposed concentrically about the first and second extension/contraction drive shafts, wherein the first transfer mechanism is configured to be driven to extend and contract by the first extension/contraction drive shaft so as to transfer a first transfer unit along a transfer object transfer direction, and the second transfer mechanism is configured to be driven to extend and contract by the second extension/contraction drive shaft so as to transfer a second transfer unit along the transfer object transfer direction, the first and second transfer mechanisms have first and second turning drive members that are driven by the first and second turning drive shafts, respectively, and turn the first and second transfer mechanisms, respectively, about the rotating axis as a center, and the first transfer mechanism and the second transfer mechanism are disposed opposite to each other in the transfer object transfer direction with the rotating axis in between.

Furthermore, the present invention is the transfer device in which the first and second transfer mechanisms are disposed at a same height position.

Furthermore, the present invention is a transfer device including a first transfer device and a second transfer device, the first transfer device comprises first and second extension/contraction drive shafts for driving extension and contraction of first and second transfer mechanisms, the first and second extension/contraction drive shafts being disposed concentrically about a predetermined rotating axis as a center, and each provided in an independently rotatable manner in a horizontal plane; and first and second turning drive shafts for turning the first and second transfer mechanisms, the first and second turning drive shafts being disposed concentrically about the first and second extension/contraction drive shafts, wherein the first transfer mechanism is configured to be driven to extend and contract by the first extension/contraction drive shaft so as to transfer a first transfer unit along a transfer object transfer direction, and the second transfer mechanism is configured to be driven to extend and contract by the second extension/contraction drive shaft so as to transfer a second transfer unit along the transfer object transfer direction, the first and second transfer mechanisms have first and second turning drive members that are driven by the first and second turning drive shafts, respectively, and turn the first and second transfer mechanisms, respectively, about the rotating axis as a center, and the first transfer mechanism and the second transfer mechanism are disposed opposite to each other in the transfer object transfer direction with the rotating axis in between; and the second transfer device comprises third and fourth extension/contraction drive shafts for driving extension and contraction of third and fourth transfer mechanisms corresponding to the first and second transfer mechanisms, the third and forth transfer mechanisms being disposed concentrically about the rotating axis as a center and each provided in an independently rotatable manner in a horizontal plane, wherein the third and fourth transfer mechanisms are disposed at height positions different from the first and second transfer mechanisms and opposite to each other in the transfer object transfer direction with the rotating axis in between, and are configured to be driven to extend and contract by the third and fourth extension/contraction drive shafts, respectively, so as to transfer third and fourth transfer units, respectively, along the transfer object transfer direction, and have a linkage mechanism connected with each of the first and second turning drive members provided to the first and second transfer mechanisms, and are configured to turn the third and fourth transfer mechanisms by the linkage mechanism about the rotating axis as a center.

Furthermore, the present invention is the transfer device, wherein the first and second transfer mechanisms are disposed at a same height, and the third and fourth transfer mechanisms are disposed at a same height.

Furthermore, the present invention is a vacuum apparatus including a vacuum chamber; and a transfer device provided in the vacuum chamber, the transfer device comprises: first and second extension/contraction drive shafts for driving extension and contraction of first and second transfer mechanisms, the first and second extension/contraction drive shafts being disposed concentrically about a predetermined rotating axis as a center, each provided in an independently rotatable manner in a horizontal plane; and first and second turning drive shafts for turning the first and second transfer mechanisms, the first and second turning drive shafts being disposed concentrically about the first and second extension/contraction drive shafts, wherein the first transfer mechanism is configured to be driven to extend and contract by the first extension/contraction drive shaft so as to transfer a first transfer unit along a transfer object transfer direction, and the second transfer mechanism is configured to be driven to extend and contract by the second extension/contraction drive shaft so as to transfer a second transfer unit along the transfer object transfer direction, the first and second transfer mechanisms have first and second turning drive members that are driven by the first and second turning drive shafts, respectively, and turn the first and second transfer mechanisms, respectively, about the rotating axis as a center, and the first transfer mechanism and the second transfer mechanism are disposed opposite to each other in the transfer object transfer direction with the rotating axis in between.

Furthermore, the present invention provides the vacuum apparatus further including a pair of transfer object detection sensors for detecting a pair of transfer objects transferred by the first and second transfer mechanisms, respectively, the pair of transfer object detection sensors being made of a plurality of sensors provided in the vacuum chamber; and a controller that controls movement of each of the first and second turning drive shafts so that the pair of transfer objects are placed on a pair of transfer object placement units on the basis of a result of detection by the pair of transfer object detection sensors.

According to the present invention, the first and second turning drive shafts configured to turn the first and second transfer mechanisms, respectively, are disposed concentrically with the first and second extension/contraction drive shafts that drive extension and contraction of the first and second transfer mechanisms, respectively, and these first and second turning drive shafts drive the first and second turning drive members, respectively, to turn the first and second transfer mechanisms, respectively, with the rotating axis as a center. This configuration makes it possible to adjust the distance between the transfer object mounting units of the first and second transfer mechanisms disposed opposite to each other in the transfer object transfer direction with the rotating axis in between and, for example, at the same height position, by spacing them apart from each other and approaching them to each other.

Consequently, according to the present invention, in the case where two transfer objects are placed side by side, the substrate mounting units of the first and second transfer mechanisms can be correctly positioned with respect to these transfer objects as well as portions where these transfer objects are placed. This makes it possible to facilitate positioning operations, and also improve throughput in transferring substrates.

Furthermore, a first transfer device may be configured as the transfer device described above, and a second transfer device may be configured such that: the second transfer device includes the third and fourth extension/contraction drive shafts disposed concentrically with the rotating axis as a center, each provided in an independently rotatable manner in a horizontal plane, and configured to drive extension and contraction of the third and fourth transfer mechanisms corresponding to the first and second transfer mechanisms, respectively, wherein the third and fourth transfer mechanisms: are disposed at height positions different from those of the first and second transfer mechanisms and opposite to each other in the transfer object transfer direction with the rotating axis in between are configured to be driven by the third and fourth extension/contraction drive shafts, respectively, to extend and contract so as to transfer the third and fourth transfer units, respectively, along the transfer object transfer direction; include the linkage mechanism connected with the first and second turning drive members provided to the first and second transfer mechanisms, respectively; and are configured to turn the third and fourth transfer mechanisms by the linkage mechanism with the rotating axis as a center. In the case where this configuration is employed, it is possible to adjust the distance between the substrate mounting units of the third and fourth transfer mechanisms by causing the third and fourth transfer mechanisms to extend and contract by the third and fourth extension/contraction drive shafts, spacing the substrate mounting units apart from each other, and approaching them to each other.

Consequently, according to the present invention, substrates can be transferred by the first and second transfer mechanisms and the third and fourth transfer mechanisms, which further improves throughput in transferring substrates.

### Effect of the Invention

According to the present invention, it is possible to provide a system that facilitates positioning operation, and also improves throughput in transferring substrates in a transfer device that can transfer a pair of transfer objects simultaneously.

### BRIEF DESCRIPTION OF THE DRAWINGS

FIGS. 1(a) and 1(b) are plan views each illustrating a lower transfer device according to an embodiment of a transfer device relating to the present invention.

FIGS. 2(a) and 2(b) are plan views each illustrating an upper transfer device according to the same embodiment.

FIG. 3(a) is a diagram illustrating a configuration of the transfer device when viewed from the downstream side in a transfer direction; FIG. 3(b) is a plan view illustrating the configuration of the transfer device; and FIG. 3(c) is a diagram illustrating the configuration of the transfer device when viewed from the upstream side in the transfer direction. FIG. 4 is a plan view illustrating extension movement of the lower transfer mechanism.

FIG. 5 is a plan view illustrating extension movement of the upper transfer mechanism.

FIGS. 6(a) and 6(b) are explanatory views illustrating small turning movement of the upper transfer device and the lower transfer device according to the present embodiment (first).

FIGS. 7(a) and 7(b) are explanatory views illustrating small turning movement of the upper transfer device and the lower transfer device according to the present embodiment (second).

FIGS. 8(a) and 8(b) are explanatory views illustrating small turning movement of the upper transfer device and the lower transfer device according to the present embodiment (third).

FIGS. 9(a) and 9(b) are explanatory views illustrating small turning movement of the upper transfer device and the lower transfer device according to the present embodiment (fourth).

FIG. 10 is a plan view illustrating an embodiment of a vacuum apparatus according to the present invention (first).

FIG. 11 is a plan view illustrating an embodiment of the vacuum apparatus according to the present invention (second).

FIG. 12 is a plan view illustrating an embodiment of the vacuum apparatus according to the present invention (third).

FIG. 13 is a plan view illustrating a configuration of another embodiment of the vacuum apparatus according to the present invention.

FIG. 14 is an explanatory view illustrating a configuration of main portions of another embodiment of the vacuum apparatus according to the present invention.

FIG. 15 is a block diagram illustrating a configuration of circuit systems in another embodiment of the vacuum apparatus according to the present invention.

FIGS. 16(a), 16(b), 16(c), 16(d) and 16 (e) are explanatory views illustrating an operation of detecting positions of substrates according to the present embodiment.

FIGS. 17(a) and 17 (b) are diagrams for explaining a problem in a conventional system (first).

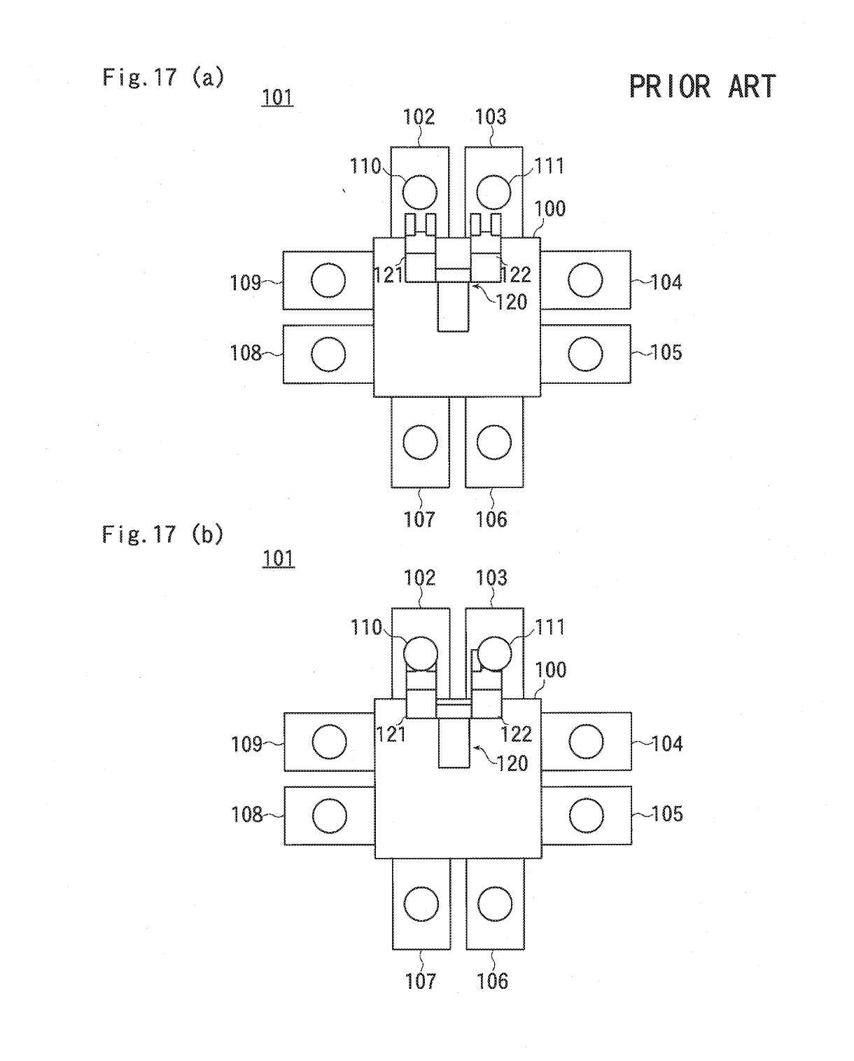

FIGS. 18(a) and 18 (b) are diagrams for explaining a problem in a conventional system (second).

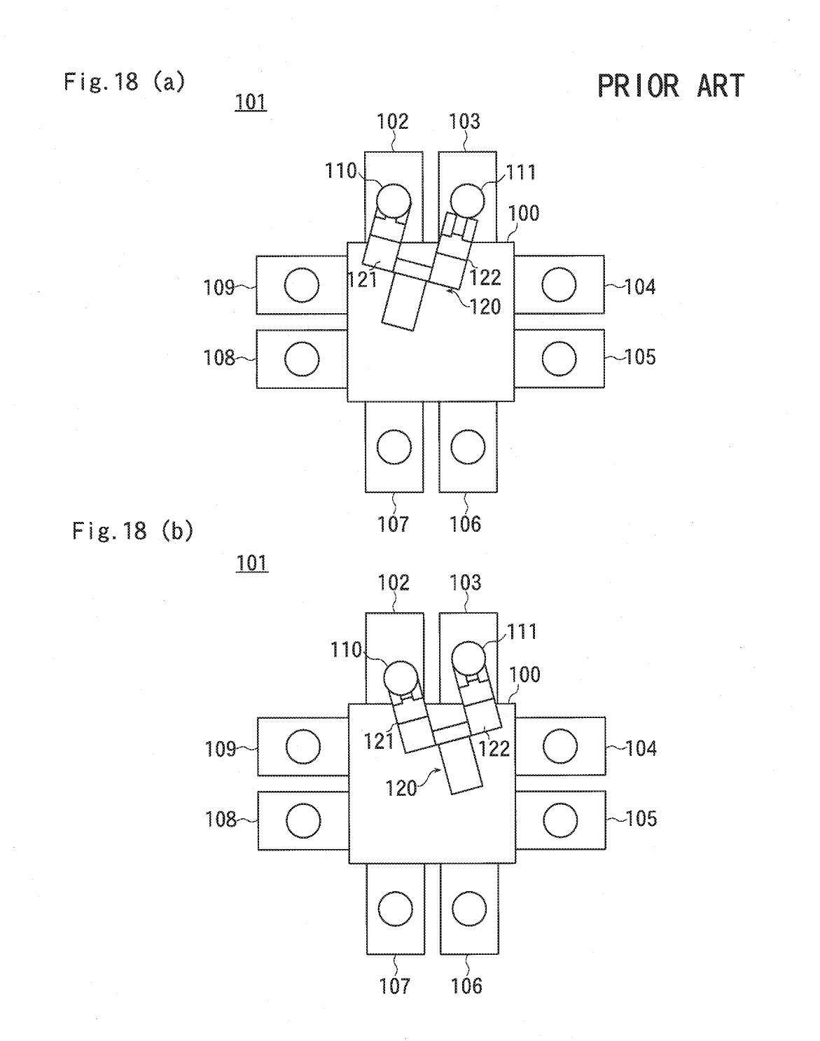

### BEST MODES FOR CARRYING OUT THE INVENTION

Hereinbelow, a preferred embodiment according to the present invention will be described in detail with reference to the drawings.

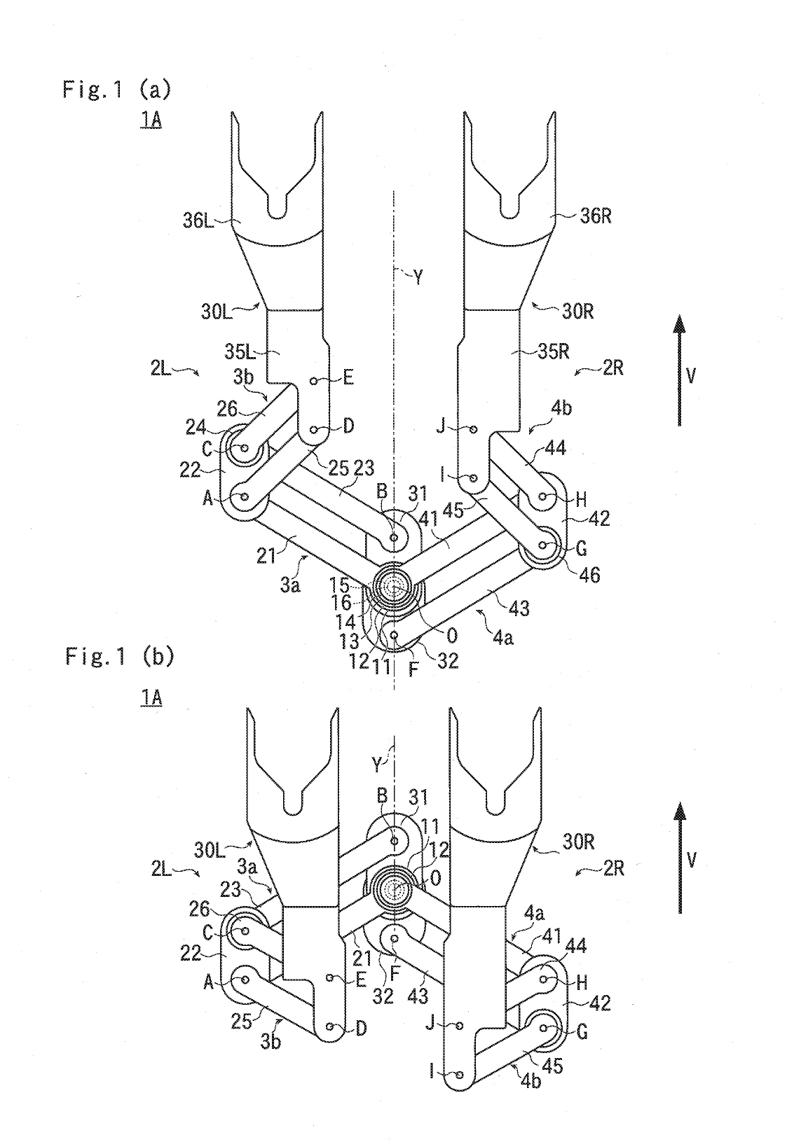

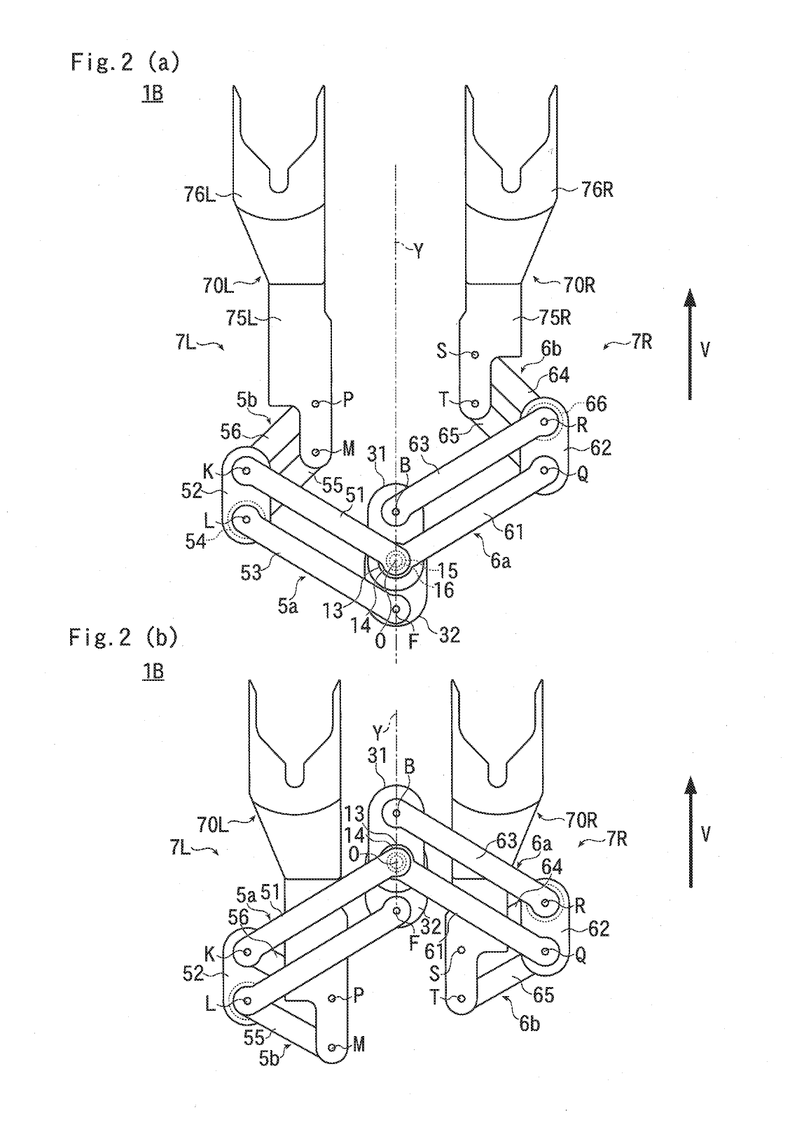

FIGS. 1(a) and 1(b) are plan views illustrating a lower transfer device according to an embodiment of a transfer device relating to the present invention. FIGS. 2(a) and 2 (b) are plan views illustrating an upper transfer device according to the same embodiment.

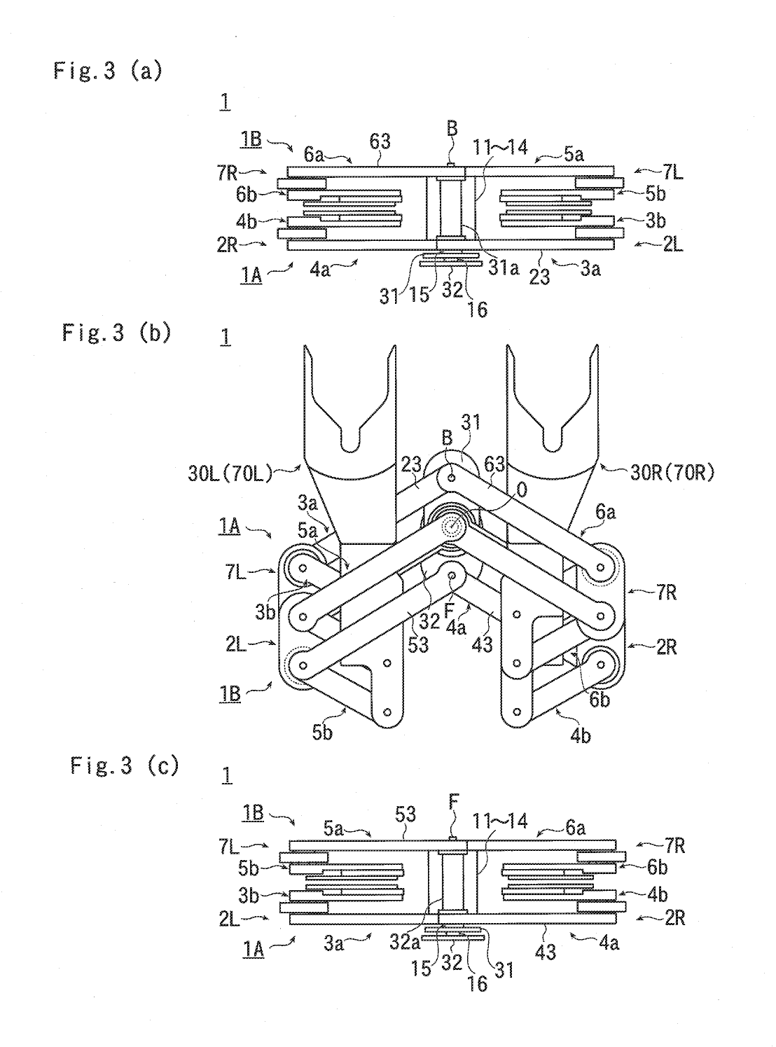

FIGS. 3(a) to 3(c) are diagrams illustrating the configuration of this transfer device. FIG. 3(a) is a diagram when viewed from the downstream side in a transfer direction; FIG. 3 (b) is a plan view; and FIG. 3(c) is a diagram when viewed from the upstream side in the transfer direction.

A transfer device 1 according to the present invention transfers a transfer object such as a substrate, for example, in a vacuum chamber (not illustrated), and includes a lower transfer device 1A serving as a first transfer device as illustrated in FIGS. 1(a) and 1 (b), and an upper transfer device 1B serving as a second transfer device as illustrated in FIGS. 2(a) and 2(b).

As illustrated in FIGS. 3 (a) to 3(c), the lower transfer device 1A and the upper transfer device 1B are arranged so as to be layered in a vertical direction.

As illustrated in FIGS. 1(a) and 1(b), this embodiment includes first, second, third, and fourth extension/contraction drive shafts 11, 12, 13, and 14 and first and second turning drive shafts 15 and 16 which are concentric and to which rotational powers in a clockwise direction or a counterclockwise direction are transmitted respectively from an independent drive source (not illustrated).

Here, the first, second, third, and fourth extension/contraction drive shafts 11 to 14 and the first and second turning drive shafts 15 and 16 are provided, for example, so as to extend in the vertical direction.

As illustrated in FIGS. 1 (a) and 1 (b), the lower transfer device 1A comprises a left lower transfer mechanism 2L and a right lower transfer mechanism 2R that are provided on both sides (that is, on the left side and the right side respectively) of a straight line Y extending from the rotating axis O in a substrate transfer direction V (in a transfer object transfer direction).

The left lower transfer mechanism 2L comprises a first left lower parallel crank mechanism 3a that is configured with a left lower driving arm 21, a first turning drive member 31, a first left lower driven arm 22, and a second left lower driven arm 23.

Here, the left lower driving arm 21 has one end portion (base end portion) connected with the first extension/contraction drive shaft 11 so as to rotate in the horizontal direction with the rotating axis O as a center.

Furthermore, the operational range of the left lower driving arm 21 is controlled such that it is located on the left side of the straight line Y passing through the rotating axis O and extending in parallel to the substrate transfer direction V.

On the other hand, the first turning drive member 31 is, for example, made up of a plate-like seating member, and is provided so as to extend toward the downstream side of the rotating axis O in the substrate transfer direction V.

This first turning drive member 31 is provided below the left lower driving arm 21, and has one end portion (base end portion) connected with a first turning drive shaft 15 so as to rotate at predetermined angles in the horizontal direction with the rotating axis O as a center.

The left lower driving arm 21 has the other end portion (tip end portion) attached to one end portion (base end portion) of the first left lower driven arm 22 at the upper portion of the left lower driving arm 21 so as to freely rotate in the horizontal direction with a supporting shaft A as a center.

Furthermore, the first turning drive member 31 has the other end portion (tip end portion) attached to one end portion (base end portion) of the second left lower driven arm 23 at the upper portion of the first turning drive member 31 so as to freely rotate in the horizontal direction with a supporting shaft B as a center.

This supporting shaft B is provided so as to extend in the vertical direction through a connecting member 31a, and is connected with a second right upper driven arm 63, which will be described later, to forma linkage mechanism (see, FIG. 3(a)).

In addition, the other end portion (tip end portion) of the second left lower driven arm 23 is attached freely rotatably in the horizontal direction at the lower portion of the first left lower driven arm 22 with the supporting shaft C as a center.

In this embodiment, the center distance between the supporting shafts A and C is set to be equal to the center distance between the rotating axis O and the supporting shaft B. In addition, the center distance between the supporting shafts B and C is set to be equal to the center distance between the rotating axis O and the supporting shaft A.

It should be noted that the center distance between the axes of the supporting shafts A and C and the center distance between the rotating axis O and the supporting shaft B are configured to be shorter than the center distance between the axes of the supporting shafts B and C and the center distance between the rotating axis O and the supporting shaft A.

The first left lower parallel crank mechanism 3a has a tip end portion, (i.e., an operation-side end portion connected with a second left lower parallel crank mechanism 3b).

This second left lower parallel crank mechanism 3b is configured with the first left lower driven arm 22 of the first left lower parallel crank mechanism 3a, a third left lower driven arm 25, a fourth left lower driven arm 26, and a supporting portion 35L of a left lower end effector 30L.

Here, an end portion of the first left lower driven arm 22 on the left lower driving arm 21 side is attached to one end portion (base end portion) of the third left lower driven arm 25 at the upper portion of the first left lower driven arm 22 so as to freely rotate in the horizontal direction with the supporting shaft A described above as a center.

Furthermore, an end portion of the first left lower driven arm 22 on the second left lower driven arm 23 side is attached to one end portion (base end portion) of the fourth left lower driven arm 26 at the upper portion of the first left lower driven arm 22 so as to freely rotate in the horizontal direction with the supporting shaft C described above as a center.

In addition, the other end portions (tip end portions) of the third and fourth left lower driven arms 25 and 26 are attached freely rotatably in the horizontal direction at the lower portion of a supporting portion 35L of the left lower end effector 30L having a substrate mounting unit 36L with the centers being a supporting shaft D and a supporting shaft E, respectively, which are provided at positions spaced apart from each other by the center distance equal to the center distance between the supporting shafts A and C. These third and fourth left lower driven arms 25 and 26 are configured such that the supporting shafts D and E for these arms are located on the side of the straight line Y passing through the rotating axis O and extending parallel to the substrate transfer direction V relative to the supporting shafts A and C, respectively.

In this embodiment, the first left lower driven arm 22 includes a power transmission mechanism 24 made up of a gear box that is configured so that the left lower driving arm 21 and the fourth left lower driven arm 26 rotate at the same angle in opposite rotation directions. In other words, power from the left lower driving arm 21 is transmitted through the power transmission mechanism 24 of the first left lower driven arm 22 to make the fourth left lower driven arm 26 rotate at the same angle in an opposite direction with respect to the left lower driving arm 21.

In this embodiment, the center distance between the supporting shafts A and C is set to be equal to the center distance between the supporting shafts D and E. Furthermore, the center distance between the supporting shafts A and D is set to be equal to the center distance between the supporting shafts C and E.

It is noted that the center distance between the supporting shafts D and E and the center distance between the supporting shafts A and C are configured to be shorter than the center distance between the supporting shafts A and D and the center distance between the supporting shafts C and E.

On the other hand, in this embodiment, the center distance between the supporting shafts A and D and the center distance between the supporting shafts C and E are set to be shorter than the center distance between the rotating axis O and the supporting shaft A and the center distance between the supporting shafts B and C, respectively.

Furthermore, this configuration makes it possible to prevent the left lower end effector 30L from being brought into contact with the first to fourth extension/contraction drive shafts 11 to 14 and the supporting shafts B and F in the case where the left lower transfer mechanism 2L is moved in the substrate transfer direction V or in the opposite direction.

On the other hand, the right lower transfer mechanism 2R according to this embodiment comprises a first right lower parallel crank mechanism 4a that is configured with a right lower driving arm 41, a second turning drive member 32, a first right lower driven arm 42, and a second right lower driven arm 43.

Here, one end portion (base end portion) of the right lower driving arm 41 is connected with the second extension/contraction drive shaft 12 so as to rotate in the horizontal direction with the rotating axis O as a center.

Furthermore, the operational range of the right lower driving arm 41 is configured to be controlled such that it is located on the right side of the straight line Y passing through the rotating axis O and extending in parallel to the substrate transfer direction V.

On the other hand, the second turning drive member 32 is, for example, configured with a plate-like seating member, and is provided so as to extend toward the upstream side of the rotating axis O in the substrate transfer direction V.

This second turning drive member 32 is provided below the first turning drive member 31 described above, and one end portion (base end portion) of the second turning drive member 32 is connected with a second turning drive shaft 16 so as to rotate at a predetermined angle in the horizontal direction with the rotating axis O being the center.

One end portion (base end portion) of the first right lower driven arm 42 is attached to the other end portion (tip end portion) of the right lower driving arm 41 at the upper portion of the right lower driving arm 41 so as to freely rotate in the horizontal direction with a supporting shaft Has a center.

Furthermore, one end portion (base end portion) of the second right lower driven arm 43 is attached to the other end portion (tip end portion) of the second turning drive member 32 at the upper portion of the second turning drive member 32 so as to freely rotate in the horizontal direction with a supporting shaft F as a center.

This supporting shaft F is provided so as to extend in the vertical direction through a connecting member 32a, and is configured to be connected with a second left upper driven arm 53, which will be described later (see FIG. 3(c)).

In addition, the other end portion (tip end portion) of the second right lower driven arm 43 is attached freely rotatably in the horizontal direction at the lower portion of the first right lower driven arm 42 with a supporting shaft Gas a center.

In this embodiment, the center distance between the supporting shafts H and G is set to be equal to the center distance between the rotating axis O and the supporting shaft F. Furthermore, the center distance between the supporting shafts F and G is set to be equal to the center distance between the rotating axis O and the supporting shaft H.

It is noted that the center distance between the supporting shafts H and G and the center distance between the rotating axis O and the supporting shaft F are configured to be shorter than the center distance between the supporting shafts F and G and the center distance between the rotating axis O and the supporting shaft H.

A second right lower parallel crank mechanism 4b is connected with a tip end portion (i.e., an operation-side end portion of the first right lower parallel crank mechanism 4a).

This second right lower parallel crank mechanism 4b is configured with the first right lower driven arm 42 of the first right lower parallel crank mechanism 4a, a third right lower driven arm 44, a fourth right lower driven arm 45, and a supporting portion 35R of a right lower end effector 30R.

Here, an end portion of the first right lower driven arm 42 on the right lower driving arm 41 side is attached to one end portion (base end portion) of the third right lower driven arm 44 at the upper portion of the first right lower driven arm 42 so as to freely rotate in the horizontal direction with the supporting shaft H described above as a center.

Furthermore, an end portion of the first right lower driven arm 42 on the second right lower driven arm 43 side is attached to one end portion (base end portion) of the fourth right lower driven arm 45 at the upper portion of the first right lower driven arm 42 so as to freely rotate in the horizontal direction with the supporting shaft G described above as a center.

In addition, the other end portions (tip end portions) of the third and fourth right lower driven arms 44 and 45 are attached freely rotatably in the horizontal direction at the lower portion of a supporting portion 35R of the right lower end effector 30R having a substrate mounting unit 36R with a supporting shaft J and a supporting shaft I being centers, respectively, which are provided at positions spaced apart from each other by the center distance equal to the center distance between the supporting shafts H and G.

These third and fourth right lower driven arms 44 and 45 are configured such that the supporting shaft J and the supporting shaft I for these arms are located on the side of the straight line Y passing through the rotating axis O and extending parallel to the substrate transfer direction V relative to the supporting shaft H and the supporting shaft G.

In this embodiment, a power transmission mechanism 46 made up of a gear box, which is configured such that the right lower driving arm 41 and the fourth right lower driven arm 45 rotate at the same angle in opposite rotation directions, is provided in the first right lower driven arm 42.

In other words, power from the right lower driving arm 41 is transmitted through the power transmission mechanism 46 of the first right lower driven arm 42 to make the fourth right lower driven arm 45 rotate at the same angle in an opposite direction with respect to the right lower driving arm 41. In this embodiment, the center distance between the supporting shafts G and His configured to be equal to the center distance between the supporting shafts I and J. Furthermore, the center distance between the supporting shafts G and I is configured to be equal to the center distance between the supporting shafts H and J.

It is noted that, in this embodiment, the center distance between the supporting shafts I and J and the center distance between the supporting shafts G and H are configured to be shorter than the center distance between the supporting shafts G and I and the center distance between the supporting shafts H and J.

On the other hand, the center distance between the supporting shafts G and I and the center distance between the supporting shafts H and J are set to be shorter than the center distance between the rotating axis O and the supporting shaft H and the center distance between the supporting shafts F and G, respectively.

Furthermore, this structural arrangement makes it possible to prevent the right lower end effector 30R from being brought into contact with the first to fourth extension/contraction drive shafts 11 to 14 and the supporting shafts B and F in the case where the right lower transfer mechanism 2R is moved along the substrate transfer direction V.

It is noted that, in this embodiment, the first left lower parallel crank mechanism 3a of the left lower transfer mechanism 2L and the first right lower parallel crank mechanism 4a of the right lower transfer mechanism 2R are configured such that the center distances between the corresponding arms of these crank mechanisms are equal to each other.

Furthermore, the second left lower parallel crank mechanism 3b of the left lower transfer mechanism 2L and the second right lower parallel crank mechanism 4b of the right lower transfer mechanism 2R are configured such that the center distances between the corresponding arms of these crank mechanisms are equal to each other.

The right lower end effector 30R according to this embodiment is configured such that the length of the supporting portion 35R in the substrate transfer direction V is longer than the length of the supporting portion 35L of the left lower end effector 30L so that the center distance from the substrate mounting unit 36R to the rotating axis O is equal to the distance from the substrate mounting unit 36L to the rotating axis O in the left lower end effector 30L.

Furthermore, in this embodiment, the shape and arrangement of each member of the left lower transfer mechanism 2L and the right lower transfer mechanism 2R are set in a manner such that the height position of the left lower end effector 30L is equal to that of the right lower end effector 30R.

As illustrated in FIGS. 2 (a) and 2 (b), the upper transfer device 1B comprises a left upper transfer mechanism 7L and a right upper transfer mechanism 7R that are provided on both sides (that is, on the left side and the right side respectively) of the straight line Y extending from the rotating axis O in the substrate transfer direction V.

The left upper transfer mechanism 7L comprises a first left upper parallel crank mechanism 5a that is configured with a left upper driving arm 51, the second turning drive member 32 described above, a first left upper driven arm 52, and the second left upper driven arm 53.

Here, the left upper driving arm 51 has one end portion (base end portion) connected with a fourth extension/contraction drive shaft 14 so as to rotate in the horizontal direction with the rotating axis O as a center.

Furthermore, the operational range of the left upper driving arm 51 is configured to be controlled such that it is located on the left side of the straight line Y passing through the rotating axis O and extending in parallel to the substrate transfer direction V.

In the other end portion (tip end portion) of the left upper driving arm 51, one end portion (base end portion) of the first left upper driven arm 52 is rotatably attached in the horizontal direction with a supporting shaft K as a center at the lower portion of the left upper driving arm 51a.

Furthermore, in the other end portion (tip end portion) of the second turning drive member 32, the one end portion (base end portion) of the second left upper driven arm 53 is rotatably attached in the horizontal direction with the supporting shaft F as a center above the second turning drive member 32.

Here, the supporting shaft F is provided through a connecting member 32a extending in the vertical direction as described above, and the second left upper driven arm 53 is attached to the supporting shaft F so as to have the same height as the left upper driving arm 51.

In addition, the other end portion (tip end portion) of the second left upper driven arm 53 is attached freely rotatably in the horizontal direction at the upper portion of the first left upper driven arm 52 with a supporting shaft Las a center.

In this embodiment, the center distance between the supporting shafts K and L is set to be equal to the center distance between the rotating axis O and the supporting shaft F.

Furthermore, the center distance between the supporting shafts F and L is set to be equal to the center distance between the rotating axis O and the supporting shaft K.

It is noted that the center distance between the supporting shafts K and L and the center distance between the rotating axis O and the supporting shaft F are configured to be shorter than the center distance between the supporting shafts F and L and the center distance between the rotating axis O and the supporting shaft K.

The first left upper parallel crank mechanism 5a has a tip end portion (i.e., an operation-side end portion connected with a second left upper parallel crank mechanism 5b).

This second left upper parallel crank mechanism 5b is configured with the first left upper driven arm. 52 of the first left upper parallel crank mechanism 5a, a third left upper driven arm 55, a fourth left upper driven arm 56, and a supporting portion 75L of a left upper end effector 70L.

Here, an end portion of the first left upper driven arm 52 on the left upper driving arm 51 side is attached to one end portion (base end portion) of the fourth left upper driven arm 56 at the lower portion of the first left upper driven arm 52 so as to freely rotate in the horizontal direction with the supporting shaft K described above as a center.

Furthermore, an end portion of the first left upper driven arm 52 on the second left upper driven arm 53 side is attached to one end portion (base end portion) of the third left upper driven arm 55 at the lower portion of the first left upper driven arm 52 so as to freely rotate in the horizontal direction with the supporting shaft L described above as a center.

In addition, the other end portions (tip end portions) of the third and fourth left upper driven arms 55 and 56 are attached freely rotatably in the horizontal direction at the lower portion of a supporting portion 75L of the left upper end effector 70L having a substrate mounting unit 76L with a supporting shaft M and a supporting shaft P being centers, respectively, which are provided at positions spaced apart from each other by the distance equal to the center distance between the supporting shafts L and K. These third and fourth left upper driven arms 55 and 56 are configured such that the supporting shaft M and the supporting shaft P for these arms are located on the side of the straight line Y passing through the rotating axis O and extending parallel to the substrate transfer direction V relative to the supporting shaft L and the supporting shaft K.

In this embodiment, a power transmission mechanism 54 made up of a gear box that is configured so that the left upper driving arm 51 and the third left upper driven arm 55 rotate at the same angle in opposite rotation directions is provided in the first left upper driven arm 52. In other words, power from the left upper driving arm 51 is transmitted through the power transmission mechanism 54 of the first left upper driven arm 52 to make the third left upper driven arm 55 rotate at the same angle in an opposite direction with respect to the left upper driving arm 51.

In this embodiment, the center distance between the supporting shafts K and L is set to be equal to the center distance between the supporting shafts P and M. Furthermore, the center distance between the supporting shafts K and P is set to be equal to the center distance between the supporting shafts L and M.

It is noted that the center distance between the supporting shafts P and M and the distance between the axes of the supporting shafts K and L are configured to be shorter than the center distance between the supporting shafts L and M and the center distance between the supporting shafts K and P, respectively.

On the other hand, in this embodiment, the center distance between the supporting shafts L and M and the center distance between the supporting shafts K and P are set to be shorter than the center distance between the rotating axis O and the supporting shaft K and the center distance between the supporting shafts F and L.

Furthermore, the left upper end effector 70L according to this embodiment is configured such that the height position of the upper surface thereof is located lower than the height position of the lower portion of each of the left upper driving arm 51 and the second left upper driven arm 53 of the first left upper parallel crank mechanism 5a.

Furthermore, this structural arrangement makes it possible to allow the left upper end effector 70L to pass through below the left upper driving arm 51 and the second left upper driven arm 53 and to prevent the left upper end effector 70L from being brought into contact with the first to fourth extension/contraction drive shafts 11 to 14 and the supporting shafts B and F in a case where the left upper transfer mechanism 7L is moved in the substrate transfer direction V or in the opposite direction.

On the other hand, the right upper transfer mechanism 7R according to this embodiment comprises a first right upper parallel crank mechanism 6a that is configured with a right upper driving arm 61, the first turning drive member 31, a first right upper driven arm 62, and a second right upper driven arm 63.

Here, one end portion (base end portion) of the right upper driving arm 61 is connected with the third extension/contraction drive shaft 13 so as to rotate in the horizontal direction with the rotating axis O as a center.

Furthermore, the operational range of the right upper driving arm 61 is configured to be controlled such that it is located on the right side of the straight line Y passing through the rotating axis O and extending in parallel to the substrate transfer direction V.

The other end portion (tip end portion) of the right upper driving arm 61 is attached to one end portion (base end portion) of the first right upper driven arm 62 at the lower portion of the right upper driving arm 61 so as to freely rotate in the horizontal direction with a supporting shaft Q as a center.

Furthermore, the other end portion (tip end portion) of the first turning drive member 31 is attached to one end portion (base end portion) of the second right upper driven arm 63 above the first turning drive member 31 so as to freely rotate in the horizontal direction with the supporting shaft B as a center.

Here, the supporting shaft B is provided through the connecting member 31a extending in the vertical direction as described above, and the second right upper driven arm 63 is attached to the supporting shaft B so as to have the same height as the right upper driving arm 61.

In addition, the other end portion (tip end portion) of the second right upper driven arm 63 is attached freely rotatably in the horizontal direction at the upper portion of the first right upper driven arm 62 with a supporting shaft R as a center.

In this embodiment, the center distance between the supporting shafts R and Q is set to be equal to the center distance between the rotating axis O and the supporting shaft B. Furthermore, the center distance between the supporting shafts B and R is set to be equal to the center distance between the rotating axis O and the supporting shaft Q.

It is noted that the center distance between the supporting shafts Q and R and the center distance between the rotating axis O and the supporting shaft B are configured to be shorter than the center distance between the supporting shafts B and R and the center distance between the rotating axis O and the supporting shaft Q.

A second right upper parallel crank mechanism 6b is connected with a tip end portion (i.e., an operation-side end portion of the first right upper parallel crank mechanism 6a).

This second right upper parallel crank mechanism 6b is configured with the first right upper driven arm 62 of the first right upper parallel crank mechanism 6a, a third right upper driven arm 64, a fourth right upper driven arm 65, and a supporting portion 75R of a right upper end effector 70R.

Here, an end portion of the first right upper driven arm 62 on the right upper driving arm 61 side is attached to one end portion (base end portion) of the fourth right upper driven arm 65 at the lower portion of the first right upper driven arm 62 so as to freely rotate in the horizontal direction with the supporting shaft Q described above as a center.

Furthermore, an end portion of the first right upper driven arm 62 on the second right upper driven arm 63 side is attached to one end portion (base end portion) of the third right upper driven arm 64 at the lower portion of the first right upper driven arm. 62 so as to freely rotate in the horizontal direction with the supporting shaft R described above as a center.

In addition, the other end portions (tip end portions) of the third and fourth right upper driven arms 64 and 65 are attached freely rotatably in the horizontal direction at the lower portion of the supporting portion 75R of the right upper end effector 70R with a supporting shaft T and a supporting shaft S being centers, respectively, which are provided at positions spaced apart from each other by the center distance equal to the center distance between the supporting shafts Q and R.

These third and fourth right upper driven arms 64 and 65 are configured such that the supporting shaft S and the supporting shaft T for these arms are located on the side of the straight line Y passing through the rotating axis O and extending parallel to the substrate transfer direction V relative to the supporting shaft R and the supporting shaft Q.

In this embodiment, in the first right upper driven arm 62, a power transmission mechanism 66 made up of a gear box that is configured such that the right upper driving arm 61 and the third right upper driven arm 64 rotate at the same angle in opposite rotation directions is provided in the first right upper driven arm 62. In other words, power from the right upper driving arm 61 is transmitted through the power transmission mechanism 66 of the first right upper driven arm 62 to make the third right upper driven arm 64 rotate at the same angle in an opposite direction with respect to the right upper driving arm 61.

In this embodiment, the center distance between the supporting shafts R and Q is configured to be equal to the center distance between the supporting shafts S and T. Furthermore, the center distance between the supporting shafts Q and T is configured to be equal to the center distance between the supporting shafts R and S.

It is noted that, in this embodiment, the center distance between the supporting shafts S and T and the center distance between the supporting shafts R and Q are configured to be shorter than the center distance between the supporting shafts Q and T and the center distance between the supporting shafts R and S.

On the other hand, in this embodiment, the center distance between the supporting shafts Q and T and the center distance between the supporting shafts R and S are set to be shorter than the center distance between the rotating axis O and the supporting shaft Q and the center distance between the supporting shafts B and R, respectively.

Furthermore, the right upper end effector 70R according to this embodiment is configured such that the height position of the upper surface thereof is located lower than the height position of the lower portion of each of the right upper driving arm 61 and the second right upper driven arm 63 of the first right upper parallel crank mechanism 6a.

Furthermore, this configuration makes it possible to allow the right upper end effector 70R to pass through below the right upper driving arm 61 and the second right upper driven arm 63 and to prevent the right upper end effector 70R from being brought into contact with the first to fourth extension/contraction drive shafts 11 to 14 and the supporting shafts B and F in the case where the right upper transfer mechanism 7R is moved in the substrate transfer direction V or in the opposite direction.

It is noted that, in this embodiment, the first left upper parallel crank mechanism 5a of the left upper transfer mechanism 7L and the first right upper parallel crank mechanism 6a of the right upper transfer mechanism 7R are configured such that the center distances between the corresponding arms of these crank mechanisms are equal to each other.

Furthermore, the second left upper parallel crank mechanism 5b of the left upper transfer mechanism 7L and the second right upper parallel crank mechanism 6b of the right upper transfer mechanism 7R are configured such that the center distances between the corresponding arms of these crank mechanisms are equal to each other.

The right upper end effector 70R according to this embodiment is configured such that the length of the supporting portion 75R in the substrate transfer direction V is shorter than the length of the supporting portion 75L of the left upper end effector 70L so that the distance from the substrate mounting unit 76R to the rotating axis O is equal to the distance from the substrate mounting unit 76L to the rotating axis O in the left upper end effector 70L.

Next, the operation of this embodiment of the invention hereinafter will be described.

First, a description will be made of a case where the lower transfer device 1A is caused to extend.

In this case, the first extension/contraction drive shaft 11 is caused to rotate at a predetermined angle in a clockwise direction from a home position as illustrated in FIGS. 1(b) and 3(b), and the second extension/contraction drive shaft 12 is caused to rotate at a predetermined angle (for example, the same degree of angle) in a counterclockwise direction.

With these operations, the rotational power from the left lower driving arm 21 of the lower transfer device 1A connected with the first extension/contraction drive shaft 11 energizes, in the substrate transfer direction V, the first left lower parallel crank mechanism 3a and the second left lower parallel crank mechanism 3b to move these mechanisms in this direction, at the same time, the rotational power from the right lower driving arm 41 of the lower transfer device 1A connected with the second extension/contraction drive shaft 12 energizes, in the substrate transfer direction V, the first right lower parallel crank mechanism 4a and the second right lower parallel crank mechanism 4b to move these mechanisms in this direction.

With these operations, both the left lower end effector 30L and the right lower end effector 30R of the lower transfer device 1A are disposed on the downstream side relative to the rotating axis O in the substrate transfer direction V as illustrated in FIGS. 1(a) and 4.

On the other hand, as for the upper transfer device 1B, the third and fourth extension/contraction drive shafts 13 and 14 are not operated; and thus, the rotational power is not provided, so that the upper transfer device 1B is at rest. These operations can bring the left lower transfer mechanism 2L and the right lower transfer mechanism 2R of the lower transfer device 1A into an extended state as illustrated in FIG. 4.

On the other hand, the left lower transfer mechanism 2L and the right lower transfer mechanism 2R of the lower transfer device 1A can be brought back to the home position by performing reversed operations with respect to those described above; in other words, the first extension/contraction drive shaft 11 is rotated in a counterclockwise direction, and the second extension/contraction drive shaft 12 is rotated in a clockwise direction.

Furthermore, the upper transfer device 1B can be caused to extend by rotating the fourth extension/contraction drive shaft 14 at a predetermined angle in a clockwise direction from a home position as illustrated in FIGS. 2 (b) and 3(b), and by rotating the third extension/contraction drive shaft 13 at a predetermined angle (for example, the same degree of angle) in a counterclockwise direction.

With these operations, the rotational power from the left upper driving arm 51 of the upper transfer device 1B connected with the fourth extension/contraction drive shaft 14 energizes, in the substrate transfer direction V, the first left upper parallel crank mechanism 5a and the second left upper parallel crank mechanism 5b to move these mechanisms in this direction, at the same time, the rotational power from the right upper driving arm 61 of the upper transfer device 1B connected with the third extension/contraction drive shaft 13 energizes, in the substrate transfer direction V, the first right upper parallel crank mechanism 6a and the second right upper parallel crank mechanism 6b to move these mechanisms in this direction.

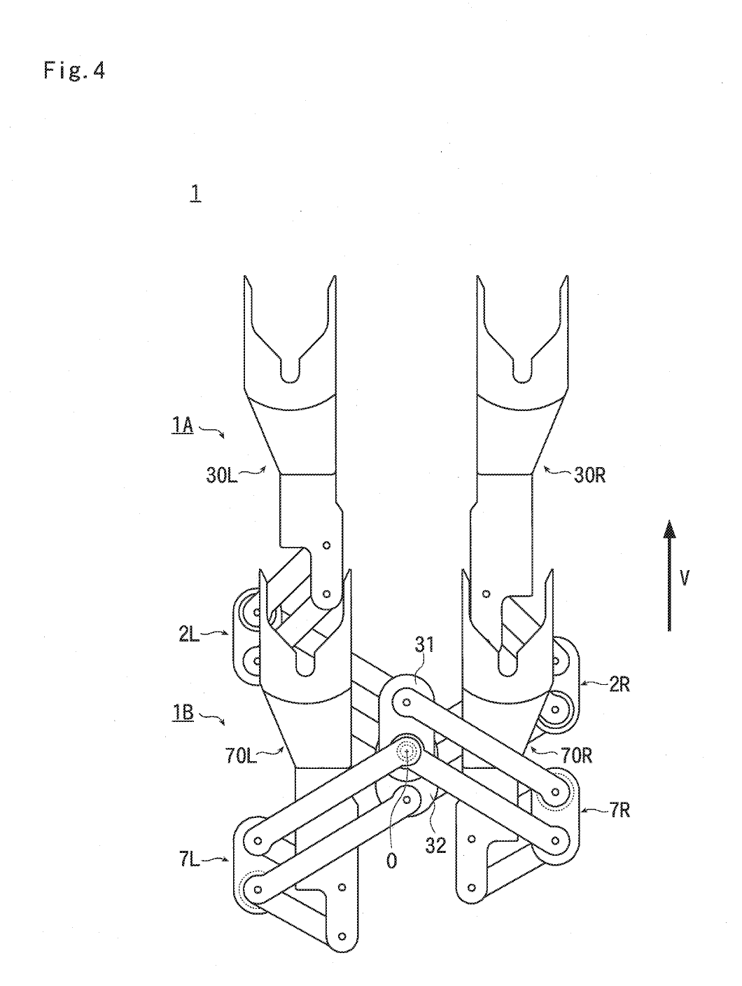

With these operations, both the left upper end effector 70L and the right upper end effector 70R of the upper transfer device 1B are disposed on the downstream side relative to the rotating axis O in the substrate transfer direction V as illustrated in FIGS. 2(a) and 5.

On the other hand, as for the lower transfer device 1A, the first and second extension/contraction drive shafts 11 and 12 are not operated, and thus the rotational power is not provided, so that the lower transfer device 1A is at rest.

These operations bring the left upper transfer mechanism 7L and the right upper transfer mechanism 7R of the upper transfer device 1B into an extended state as illustrated in FIG. 5.

On the other hand, the left lower transfer mechanism 2L and the right lower transfer mechanism 2R of the lower transfer device 1A can be brought back to the home position by performing reversed operations with respect to those described above; in other words, the first extension/contraction drive shaft 11 is rotated in a counterclockwise direction, and the second extension/contraction drive shaft 12 is rotated in a clockwise direction.

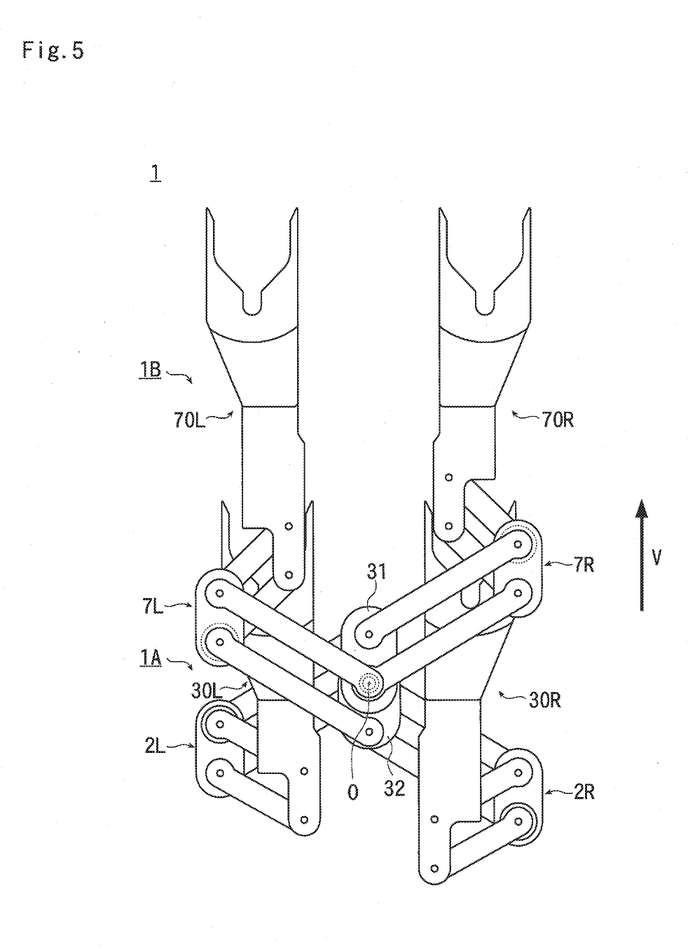

FIGS. 6 (a) and 6 (b) to FIGS. 9 (a) and 9 (b) are explanatory views illustrating small turning movements of the upper transfer device and the lower transfer device according to this embodiment.

It is noted that, in the following description, for the purpose of facilitating understanding operations, description will be made of an example in which a small turning movement is performed in a state where the lower transfer device 1A and the upper transfer device 1B are in an extended state. However, the present invention is not limited to this. It may be possible to perform the small turning movement at the time when the lower transfer device 1A or the upper transfer device 1B described above is caused to extend.

FIG. 6 (a) is an explanatory view illustrating the lower transfer device 1A being in a separating operation; and FIG. 6 (b) is an explanatory view illustrating operations performed by the upper transfer device 1B related to the separating operation.

In this case, in a state where the lower transfer device 1A is extended (see, FIG. 4), the first turning drive member 31 is caused to rotate at a predetermined small angle (for example, approximately 5 degrees) in a counterclockwise direction with the rotating axis O as a center using the rotational power from the first turning drive shaft 15, and the second turning drive member 32 is caused to rotate at a predetermined small angle (for example, approximately 5 degrees) in a clockwise direction with the rotating axis O as a center using the rotational power from the second turning drive shaft 16.

With these operations, the first left lower parallel crank mechanism 3a rotates and moves in a counterclockwise direction with the rotating axis O as a center using the rotational power from the first turning drive member 31, and the second left lower parallel crank mechanism 3b rotates and moves in a counterclockwise direction with the supporting shaft A as a center.

Consequently, the left lower transfer mechanism 2L turns at a small angle in a direction in which the left lower end effector 30L is spaced away from the straight line Y extending from the rotating axis O in the substrate transfer direction V as illustrated in FIG. 6(a).

On the other hand, the first right lower parallel crank mechanism 4a rotates and moves in a clockwise direction with the rotating axis O as a center using the rotational power from the second turning drive member 32, and the second right lower parallel crank mechanism 4b rotates and moves in a clockwise direction with the supporting shaft H as a center.

Consequently, the right lower transfer mechanism 2R turns in a direction in which the right lower end effector 30R is spaced away from the straight line Y extending from the rotating axis O in the substrate transfer direction V as illustrated in FIG. 6(a).

With these operations, it is possible to perform operation (open) of spacing the left lower end effector 30L and the right lower end effector 30R of the lower transfer device 1A apart from each other.

On the other hand, in this embodiment, the second left lower driven arm 23 of the lower transfer device 1A is connected with the second right upper driven arm 63 of the upper transfer device 1B through the connecting member 31a extending in the vertical direction, and the second left lower driven arm 23 and the second right upper driven arm 63 are attached to each other rotatably in a horizontal direction with the supporting shaft B as a center as illustrated FIGS. 3 (a) and 3(b). Thus, in association with rotation of the first turning drive member 31, the first right upper parallel crank mechanism 6a of the upper transfer device 1B rotates and moves in a counterclockwise direction with the rotating axis O as a center, and the second right upper parallel crank mechanism 6b rotates and moves in a counterclockwise direction with the supporting shaft Q as a center.

Consequently, the right upper transfer mechanism 7R turns in a direction in which the right upper end effector 70R of the upper transfer device 1B approaches the straight line Y extending from the rotating axis O in the substrate transfer direction V as illustrated in FIG. 6(b).

In addition, as illustrated in FIGS. 3(b) and 3(c), the second right lower driven arm 43 of the lower transfer device 1A is connected with the second left upper driven arm 53 of the upper transfer device 1B through the connecting member 32a extending in the vertical direction, and the second right lower driven arm 43 and the second left upper driven arm 53 are attached to each other rotatably in a horizontal direction with the supporting shaft F as a center. Thus, in association with rotation of the second turning drive member 32, the first left upper parallel crank mechanism 5a of the upper transfer device 1B rotates and moves in a clockwise direction with the rotating axis O as a center, and the second left upper parallel crank mechanism 5b rotates and moves in a clockwise direction with the supporting shaft K as a center.

Consequently, the left upper transfer mechanism 7L turns in a direction in which the left upper end effector 70L of the upper transfer device 1B approaches the straight line Y extending from the rotating axis O in the substrate transfer direction V as illustrated in FIG. 6(b).

The operations described above also make the left upper transfer mechanism 7L and the right upper transfer mechanism 7R of the upper transfer device 1B operate so as to approach each other at the same time in association with the operation of the left lower transfer mechanism 2L and the right lower transfer mechanism 2R of the lower transfer device 1A; however, the upper transfer device 1B is in a contracted state and is located at the home position. Hence, this approach does not pose any particular problem.

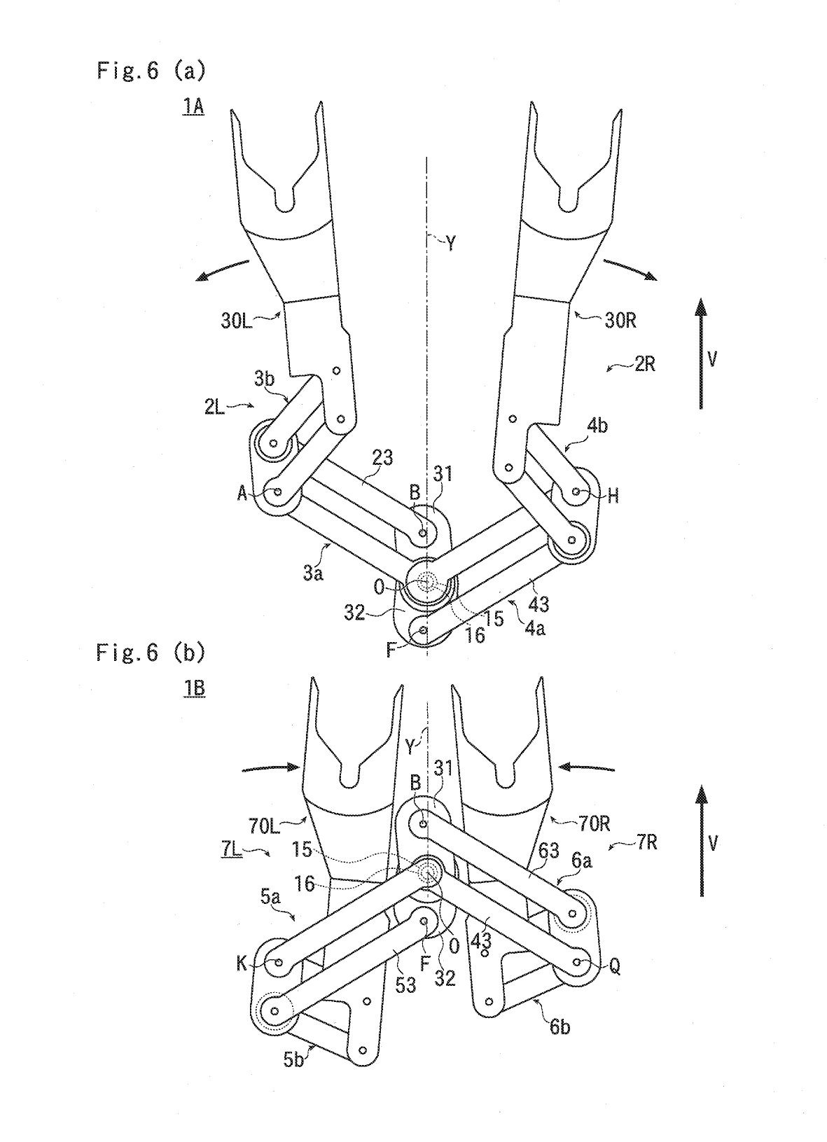

FIG. 7(a) is an explanatory view illustrating an approaching operation of the lower transfer device 1A; and FIG. 7(b) is an explanatory view illustrating an associating operation of the upper transfer device 1B.

In this case, in a state where the lower transfer device 1A is extended, the first turning drive member 31 is caused to rotate at a small angle (for example, approximately 5 degrees) in a clockwise direction with the rotating axis O as a center using the rotational power from the first turning drive shaft 15, and the second turning drive member 32 is caused to rotate at a small angle (for example, approximately 5 degrees) in a counterclockwise direction with the rotating axis O as a center using the rotational power from the second turning drive shaft 16.

With these operations, power acting in a direction opposite to the separating operation of the lower transfer device 1A as described above is transmitted (details thereof are omitted), and the left lower transfer mechanism 2L and the right lower transfer mechanism 2R are caused to turn in a direction in which the left lower end effector 30L and the right lower end effector 30R of the lower transfer device 1A each approach the straight line Y extending from the rotating axis O in the substrate transfer direction V.

Consequently, it is possible to perform a close operation where the left lower end effector 30L and the right lower end effector 30R of the lower transfer device 1A approach each other.

It is noted that the separating operations of the left upper transfer mechanism 7L and the right upper transfer mechanism 7R of the upper transfer device 1B associated with these approaching operations as described above, are performed in a state where the upper transfer device 1B is in a contracted state, and is located at the home position, as described above. Hence, these operations do not pose any particular problem (see, FIG. 7 (b)).

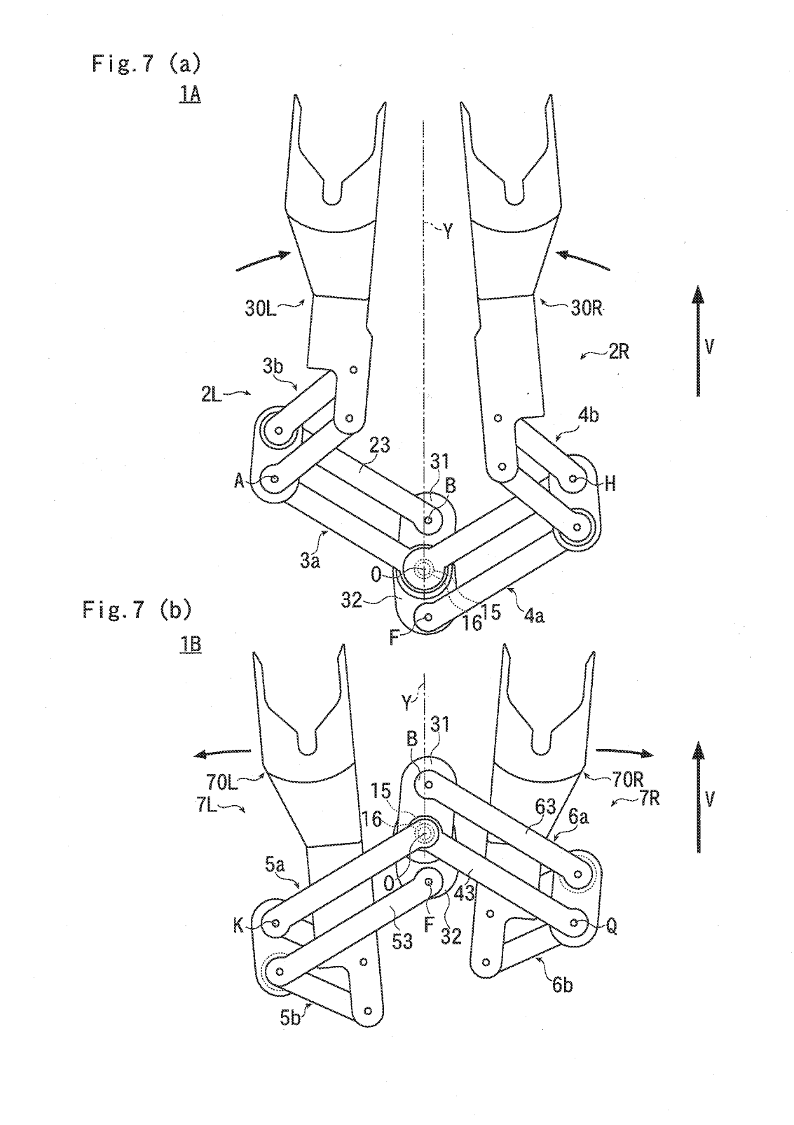

FIG. 8 (a) is a diagram illustrating a separating operation of the upper transfer device 1B.

In this case, in a state where the upper transfer device 1B is extended (see, FIG. 5), the first turning drive member 31 is caused to rotate at a predetermined small angle (for example, approximately 5 degrees) in a clockwise direction with the rotating axis O as a center using the rotational power from the first turning drive shaft 15, and the second turning drive member 32 is caused to rotate at a predetermined small angle (for example, approximately 5 degrees) in a counterclockwise direction with the rotating axis O as a center using the rotational power from the second turning drive shaft 16.

With these operations, the first right upper parallel crank mechanism 6a rotates and moves in a clockwise direction with the rotating axis O as a center using the rotational power from the first turning drive member 31, and the second right upper parallel crank mechanism 6b rotates and moves in a clockwise direction with the supporting shaft Q as a center.

Consequently, the right upper transfer mechanism 7R turns in a direction in which the right upper end effector 70R is spaced away from the straight line Y extending from the rotating axis O in the substrate transfer direction V as illustrated in FIG. 8(a).

On the other hand, the first left upper parallel crank mechanism 5a rotates and moves in a counterclockwise direction with the rotating axis O as a center using the rotational power from the second turning drive member 32, and the second left upper parallel crank mechanism 5b rotates and moves in a counterclockwise direction with the supporting shaft K as a center.

Consequently, the left upper transfer mechanism 7L turns in a direction in which the left upper end effector 70L is spaced away from the straight line Y extending from the rotating axis O in the substrate transfer direction V as illustrated in FIG. 8(a).

With these operations, it is possible to perform operation of spacing the left upper end effector 70L and the right upper end effector 70R of the upper transfer device 1B apart from each other.

Furthermore, in this embodiment, as illustrated in FIGS. 3 (a) and 3 (b), the second right upper driven arm 63 of the upper transfer device 1B is connected with the second left lower driven arm 23 of the lower transfer device 1A through the connecting member 31a extending in the vertical direction, and the second right upper driven arm 63 and the second left lower driven arm 23 are attached to each other rotatably in a horizontal direction with the supporting shaft B as a center. Thus, in association with the rotation of the first turning drive member 31, the first left lower parallel crank mechanism 3a of the lower transfer device 1A rotates and moves in a clockwise direction with the rotating axis O as a center, and the second left lower parallel crank mechanism 3b rotates and moves in a clockwise direction with the supporting shaft A as a center.

Consequently, the left lower transfer mechanism 2L turns in a direction in which the left lower end effector 30L of the lower transfer device 1A approaches the straight line Y extending from the rotating axis O in the substrate transfer direction V as illustrated in FIG. 8(b).

In addition, as illustrated in FIGS. 3(b) and 3(c), the second left upper driven arm 53 of the upper transfer device 1B is connected with the second right lower driven arm 43 of the lower transfer device 1A through the connecting member 32a extending in the vertical direction, and the second left upper driven arm 53 and the second right lower driven arm 43 are attached to each other rotatably in a horizontal direction with the supporting shaft F as a center. Thus, in association with rotation of the second turning drive member 32, the first right lower parallel crank mechanism 4a of the lower transfer device 1A rotates and moves in a counterclockwise direction with the rotating axis O as a center, and the second right lower parallel crank mechanism 4b rotates and moves in a counterclockwise direction with the supporting shaft H as a center.

Consequently, the right lower transfer mechanism 2R turns in a direction in which the right lower end effector 30R of the lower transfer device 1A approaches the straight line Y extending from the rotating axis O in the substrate transfer direction V as illustrated in FIG. 8(b).

It is noted that the approaching operations of the left lower transfer mechanism 2L and the right lower transfer mechanism 2R of the lower transfer device 1A associated with these approaching operations described above are performed in a state where the lower transfer device 1A is in a contracted state as described above and is located at the home position, so that these operations do not pose any particular problem.

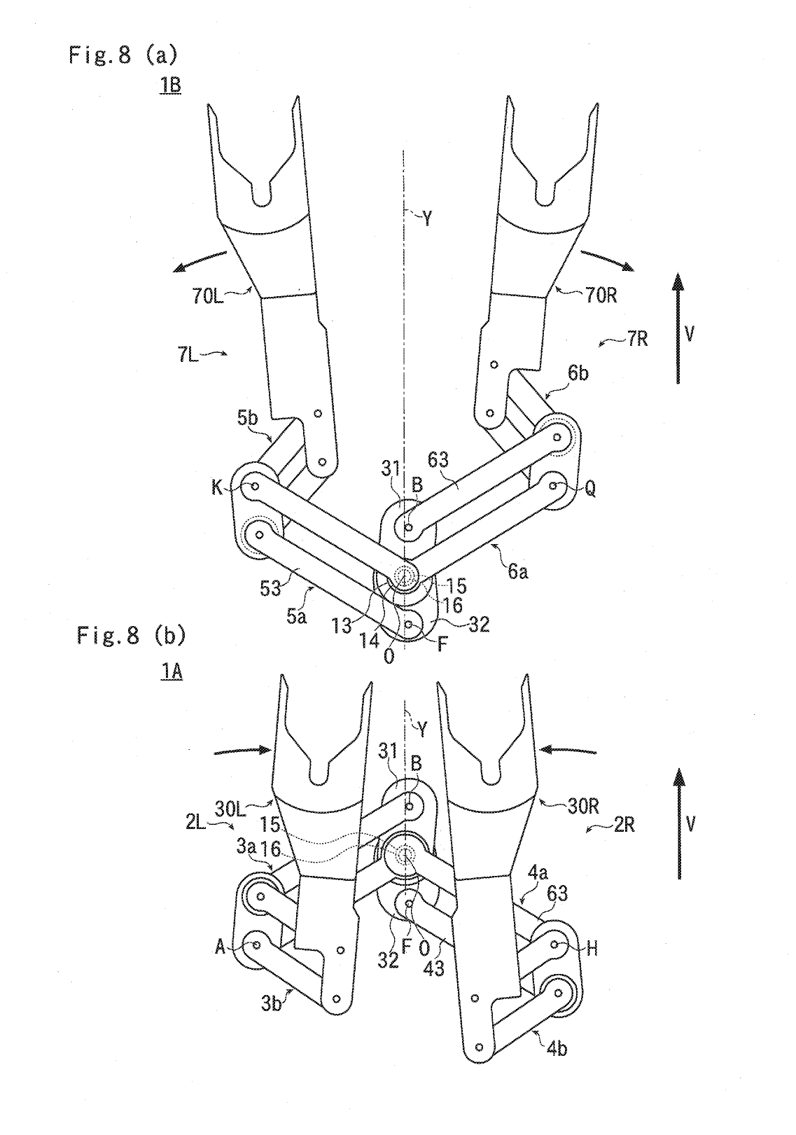

FIG. 9(a) is a diagram illustrating an approaching operation of the upper transfer device.

In this case, in a state where the upper transfer device 1B is extended, the first turning drive member 31 is caused to rotate at a predetermined small angle (for example, approximately 5 degrees) in a counterclockwise direction with the rotating axis O as a center using the rotational power from the first turning drive shaft 15, and the second turning drive member 32 is caused to rotate at a predetermined small angle (for example, approximately 5 degrees) in a clockwise direction with the rotating axis O as a center using the rotational power from the second turning drive shaft 16.

With these operations, power acting in a direction opposite to the separating operation of the upper transfer device 1B as described above is transmitted (details thereof are omitted), and the right upper transfer mechanism 7R and the left upper transfer mechanism 7L are caused to turn in a direction in which each the right upper end effector 70R and the left upper end effector 70L of the upper transfer device 1B approaches the straight line Y extending from the rotating axis O in the substrate transfer direction V.

Consequently, it is possible to perform an approaching operation where the right upper end effector 70R and the left upper end effector 70L of the upper transfer device 1B approach each other.

It is noted that the separating operations of the left lower transfer mechanism 2L and the right lower transfer mechanism 2R of the lower transfer device 1A associated with these approaching operations as described above are performed in a state where the lower transfer device 1A is in a contracted state, and is located at the home position as described above, so that these operations do not pose any particular problem (see FIG. 9(b)).

This embodiment as described above is configured such that: the first and second turning drive shafts 15 and 16 used to cause the left lower transfer mechanism 2L and the right lower transfer mechanism 2R of the lower transfer mechanism 1A, respectively, to turn are disposed concentrically with the first and second extension/contraction drive shafts 11 and 12; and these first and second turning drive shafts 15 and 16 drive the first and second turning drive members 31 and 32, respectively, to cause the left lower transfer mechanism 2L and the right lower transfer mechanism 2R to turn with the rotating axis O as a center. Thus, it is possible to adjust the distance between the left lower end effector 30L and the right lower end effector 30R of the left lower transfer mechanism 2L and the right lower transfer mechanism 2R, which are disposed on both sides of the substrate transfer direction V with the rotating axis O being disposed therebetween and at the same height position, by spacing these effectors apart from each other and approaching these effectors to each other.

Consequently, according to this embodiment, the left lower end effector 30L and the right lower end effector 30R of the lower transfer device 1A can be correctly positioned with respect to two substrates in the case where these two substrates are arranged side by side. This makes it possible to facilitate positioning operation, and also improve throughput in transferring substrates.

Furthermore, in this embodiment, the transfer device 1 as described below is configured with the lower transfer device 1A and the upper transfer device 1B provided above the lower transfer device 1A.

More specifically, this embodiment has a configuration in which: there are provided the third and fourth extension/contraction drive shafts 13 and 14 disposed concentrically with the rotating axis O as a center and provided in an independently rotatable manner in the horizontal plane; the upper transfer device 1B has the right upper transfer mechanism 7R and the left upper transfer mechanism 7L disposed above the left lower transfer mechanism 2L and the right lower transfer mechanism 2R of the lower transfer device 1A and on both sides of the substrate transfer direction V with the rotating axis O being disposed therebetween; and these right upper transfer mechanism 7R and left upper transfer mechanism 7L are caused to move in an extending and contracting manner by the third and fourth extension/contraction drive shafts 13 and 14, respectively.

Furthermore, this embodiment is configured to cause each of the right upper transfer mechanism 7R and the left upper transfer mechanism 7L of the upper transfer device 1B to turn with the rotating axis O as a center by the linkage mechanisms connected with the first and second turning drive members 31 and 32, respectively.

According to this embodiment having the configuration described above, it is possible to extend and contract the right upper transfer mechanism 7R and the left upper transfer mechanism 7L of the upper transfer device 1B by the third and fourth extension/contraction drive shafts 13 and 14, and it is also possible to adjust the distance between the left upper end effector 70L and the right upper end effector 70R by spacing these effectors apart from each other and having them approach each other. As a result, it is possible to transfer substrates with the lower transfer device 1A and the upper transfer device 1B, which makes it possible to further improve throughput in transferring substrates.

It should be noted that the transfer device according to the present invention is not limited to the embodiment described above, and various modifications can be made.

For example, in the embodiment described above, the separating operation and the approaching operation are performed on the left lower transfer mechanism 2L (the left upper transfer mechanism 7L) and the right lower transfer mechanism 2R (the right upper transfer mechanism 7R) in the lower transfer device 1A and the upper transfer device 1B. However, since the left lower transfer mechanism 2L and the right lower transfer mechanism 2R of the lower transfer device 1A and each of the left upper transfer mechanism 7L and the right upper transfer mechanism 7R of the upper transfer device 1B can be caused to extend and contract as well as turn in an independent manner, it may be possible to employ a configuration in which various operations are performed according to arrangement of a pair of substrates.

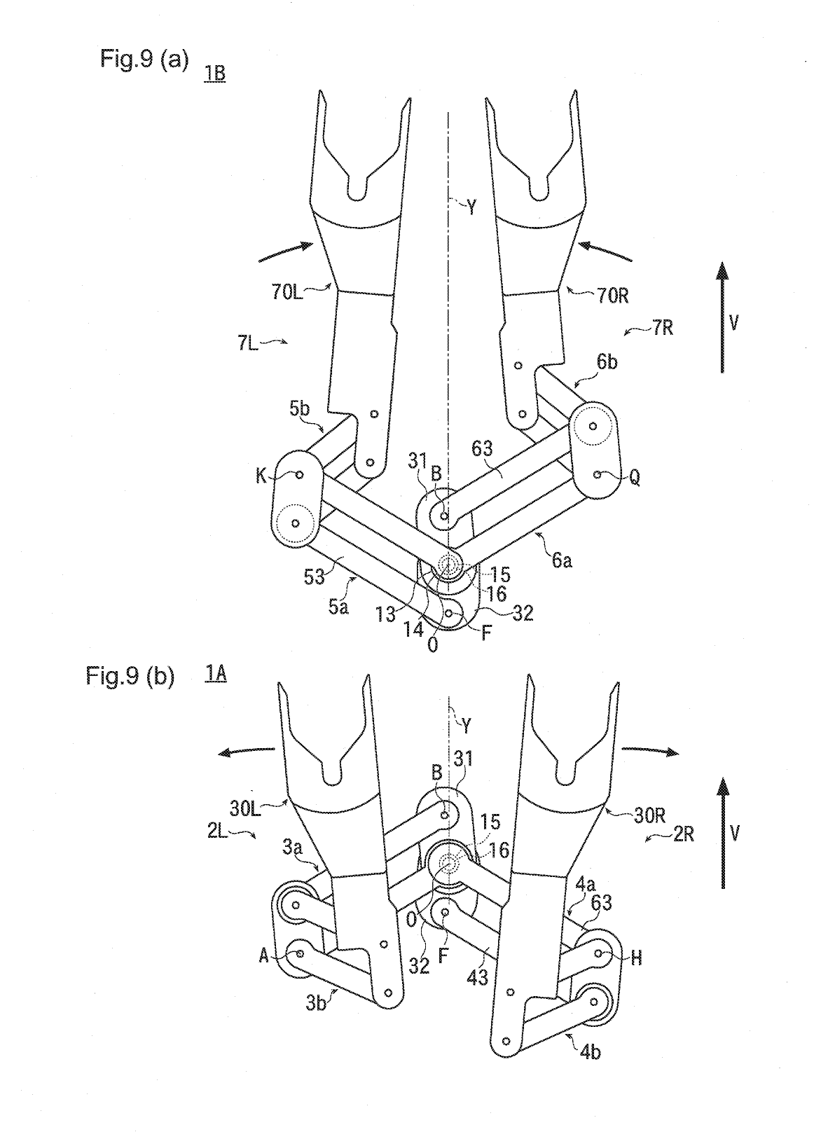

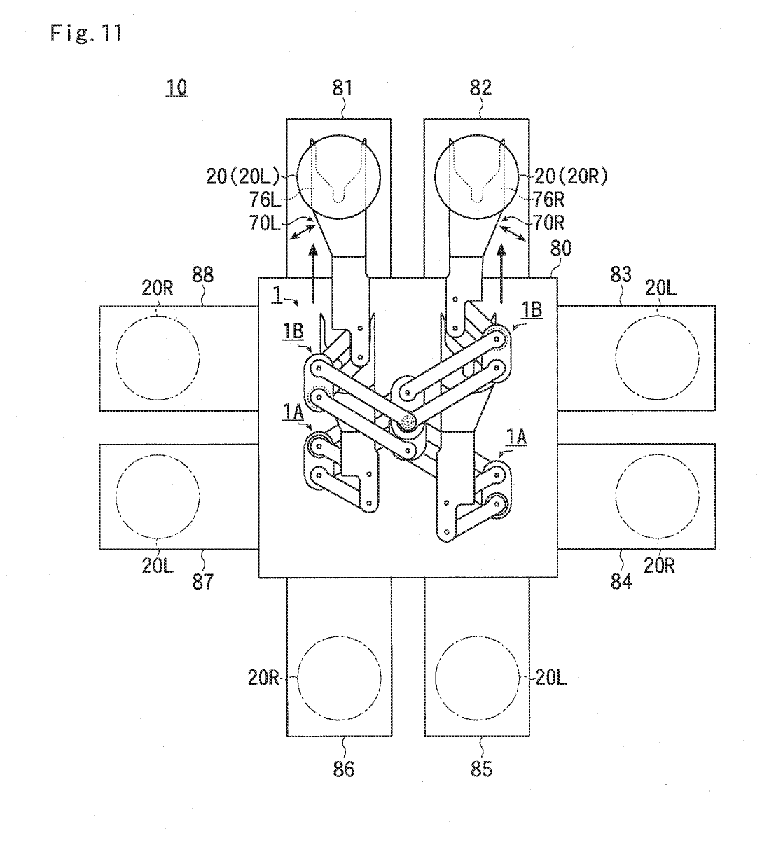

FIGS. 10 to 12 are plan views each illustrating an embodiment of a vacuum apparatus according to the present invention.

As illustrated in FIG. 10, a vacuum apparatus 10 according to this embodiment includes a rectangular transfer chamber 80 serving as a vacuum chamber connected with a vacuum exhaust system (not illustrated).

Furthermore, pairs of processing chambers 81 and 82, 83 and 84, and 87 and 88, each serving as a vacuum chamber connected with a vacuum exhaust system (not illustrated), are provided on three sides surrounding this transfer chamber 80, respectively. Furthermore, a pair of preparation chamber 85 and delivery chamber 86 are provided on the remaining side.

In these processing chambers 81 and 82, 83 and 84, 87 and 88, as well as the preparation chamber 85 and delivery chamber 86 respectively, substrate placement units 20L and 20R each serving as a transfer object placement unit are provided.

In the transfer chamber 80, the transfer device 1 as described above is provided.

Here, the transfer device 1 is provided so as to be able to turn within the transfer chamber 80, and is configured such that the lower transfer device 1A and the upper transfer device 1B can extend and contract within the transfer chamber 80.

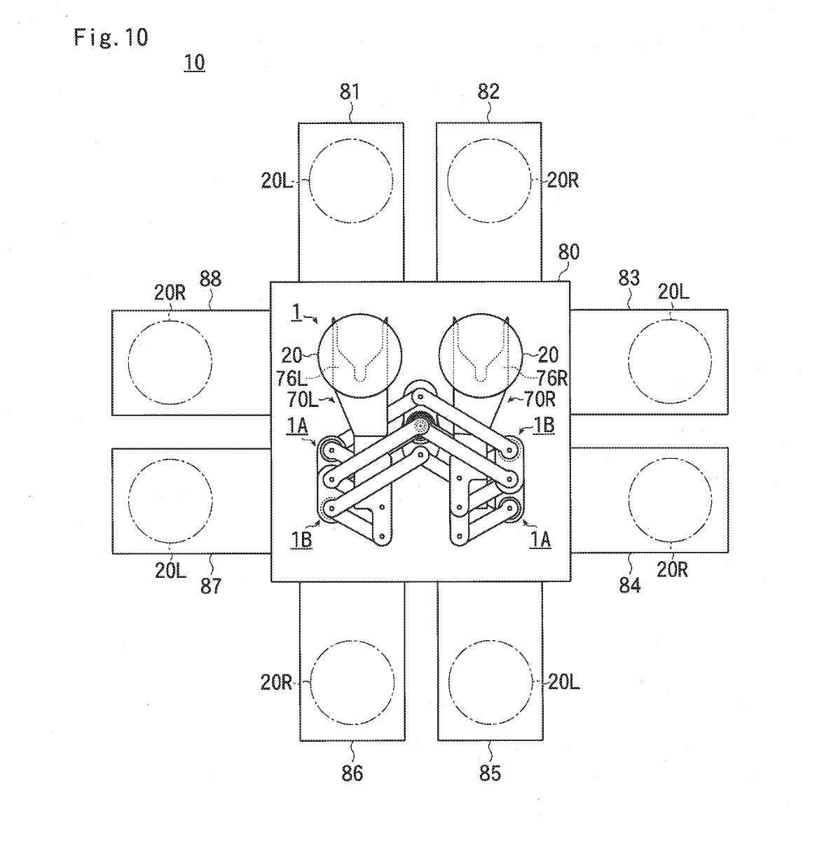

More specifically, as illustrated in FIGS. 10 to 12, configuration is made such that, for example, substrates 20 that are yet to be processed are placed on the substrate mounting units 76L and 76R of the left upper end effector 70L and the right upper end effector 70R of the upper transfer device 1B, respectively, the upper transfer device 1B is caused to extend to place the pair of substrates 20 on the substrate placement units 20L and 20R within the pair of processing chambers 81 and 82 (see FIG. 11), and then, the upper transfer device 1B is caused to contract to make the left upper end effector 70L and the right upper end effector 70R of the upper transfer device 1B return to the original positions. (The lower transfer device 1A is configured so as to operate in the same manner. Also, as for the other pairs of processing chambers 83 and 84, 87 and 88, and the pair of preparation chamber 85 and delivery chamber 86, transfer is performed in the same manner).

With the vacuum apparatus 10 according to this embodiment having the configuration as described above, when the transfer device 1 performs an extending operation, it is possible to correctly position the left upper end effector 70L and the right upper end effector 70R of the upper transfer device 1B and the left lower end effector 30L and the right lower end effector 30R of the lower transfer mechanism 1A relative to substrate placement units in a pair of processing chambers (for example, the substrate placement units 20L and 20R of the processing chambers 81 and 82) by spacing the left upper end effector 70L and the right upper end effector 70R of the upper transfer device 1B apart from each other and having them approach each other to adjust the distance between these effectors, and spacing the left lower end effector 30L and the right lower end effector 30R of the lower transfer device 1A apart from each other and having them approach each other to adjust the distance between these effectors. Thus, it is possible to easily perform positioning operation for the substrate 20, and also improve throughput in carrying in or out the substrate 20 into or from each chamber.

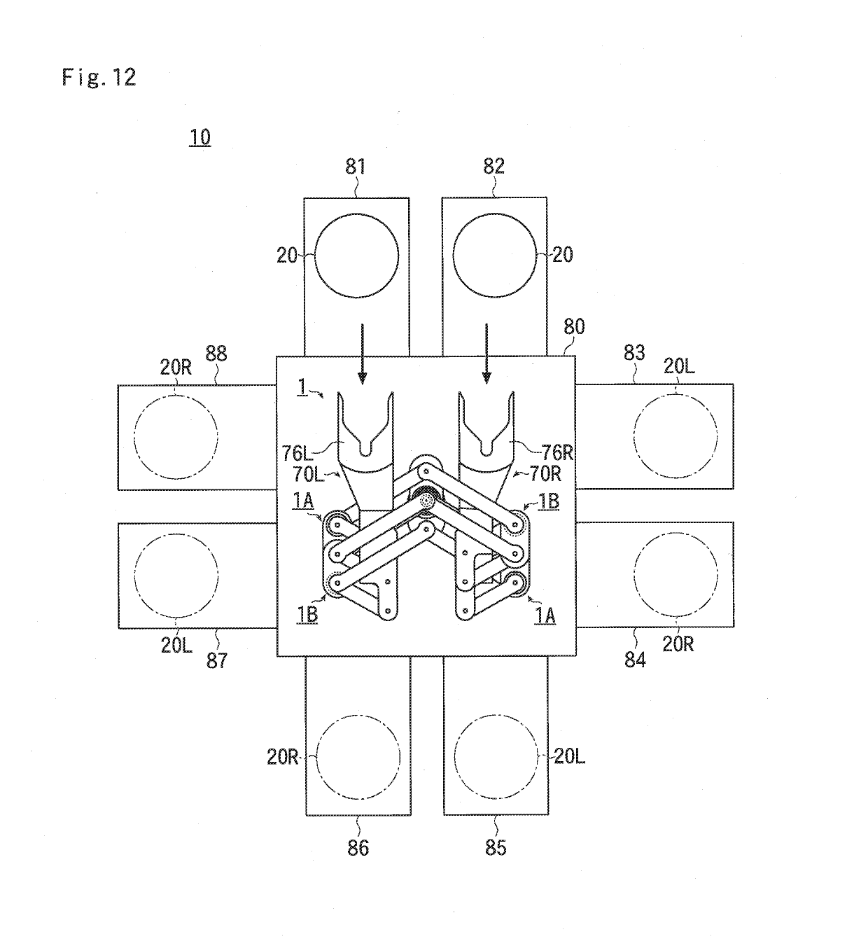

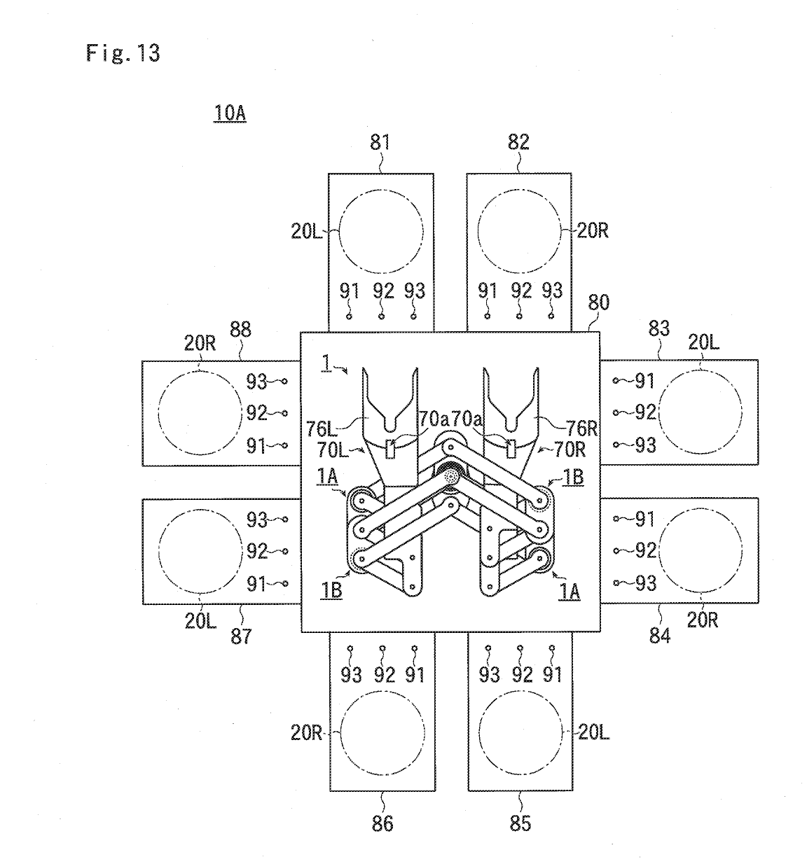

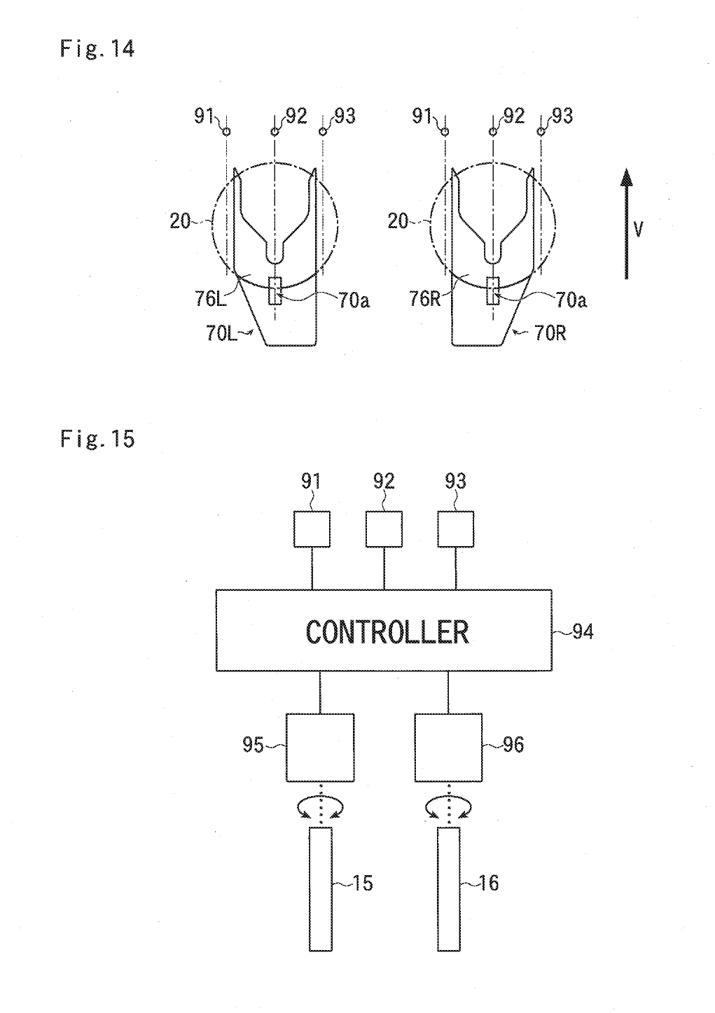

FIGS. 13 to 15 are diagrams each illustrating a configuration of another embodiment of the vacuum apparatus according to the present invention. FIG. 13 is a plan view. FIG. 14 is an explanatory view illustrating arrangement configuration of main portions. FIG. 15 is a block diagram illustrating a configuration of circuit systems. Below, the same reference numerals are attached to portions corresponding to those in the embodiment described above, and explanation thereof will not be repeated.

As illustrated in FIG. 13, in a vacuum apparatus 10A according to this embodiment, a plurality of (three in this embodiment) position sensors 91 to 93 (transfer object detection sensors) is provided in each of the above described processing chambers 81 and 82, 83 and 84, 87 and 88 and the preparation chamber 85 and the delivery chamber 86.

These position sensors 91 to 93, each made of, for example, an optical detector, are disposed between the transfer chamber 80 and the substrate placement unit 20L or substrate placement unit 20R in each of the chambers.

Here, the position sensors 91 to 93 are disposed at predetermined intervals spaced apart in a direction crossing the substrate transfer direction V as illustrated in FIG. 14.

The position sensors 91 and 93 on both sides among these position sensors 91 to 93 are disposed at a distance smaller than the width of the substrate 20 and larger than the widths of the substrate mounting unit 76L of the left upper end effector 70L and the substrate mounting unit 76R of the right upper end effector 70R of the upper transfer device 1B, as illustrated in FIG. 14.

Furthermore, this configuration makes it possible to allow the position sensors 91 and 93 to detect end edge portions at both side portions of the substrate 20 in the case where the left upper end effector 70L and the right upper end effector 70R are transferred in the substrate transfer direction V. (The left lower end effector 30L and the right lower end effector 30R of the lower transfer device 1A are configured in the same manner.)

On the other hand, the left upper end effector 70L and the right upper end effector 70R of the upper transfer device 1B each has a detection opening 70a provided for the position sensor 92 to detect the position of a substrate 20 and the positions of the left upper end effector 70L and the right upper end effector 70R. (The left lower end effector 30L and the right lower end effector 30R of the lower transfer device 1A each also has the same detection opening (not illustrated).)

This detection opening 70a is formed, for example, into a shape elongated in the substrate transfer direction V, and is provided so as to stride over the edge of the substrate mounting unit 76L, 76R of each of the left upper end effector 70L and the right upper end effector 70R. (The detection opening of each of the left lower end effector 30L and the right lower end effector 30R of the lower transfer device 1A also has the same configuration.)

On the other hand, the position sensor 92 disposed at the center among the position sensors 91 to 93 is provided on the straight line extending parallel to the substrate transfer direction V and passing through the detection opening 70a of each of the left upper end effector 70L and the right upper end effector 70R. This configuration makes it possible to allow the position sensor 92 to detect the end edge portion of the central portion of the substrate 20 and an end portion of the detection opening 70a of each of the left upper end effector 70L and the right upper end effector 70R on the upstream side in the substrate transfer direction in the case where the left upper end effector 70L and the right upper end effector 70R are transferred in the substrate transfer direction V. (The left lower end effector 30L and the right lower end effector 30R of the lower transfer device 1A each also has the same configuration.)

As illustrated in FIG. 15, the position sensors 91 to 93 according to this embodiment are connected with a controller 94 having a computer, and are each configured to send results of detection of the position sensors 91 to 93 to the controller 94.

This controller 94 stores data on a path that a predetermined specific substrate 20 takes when this substrate 20 is transferred to the substrate placement unit 20L, 20R in each of the chambers.

Furthermore, the controller 94 is connected with drive sources 95 and 96 for driving the first and second turning drive shafts 15 and 16 as described above, respectively, and is configured such that operations of the drive sources 95 and 96 are controlled in accordance with instructions that the controller 94 gives on the basis of information sent from the position sensors 91 to 93.

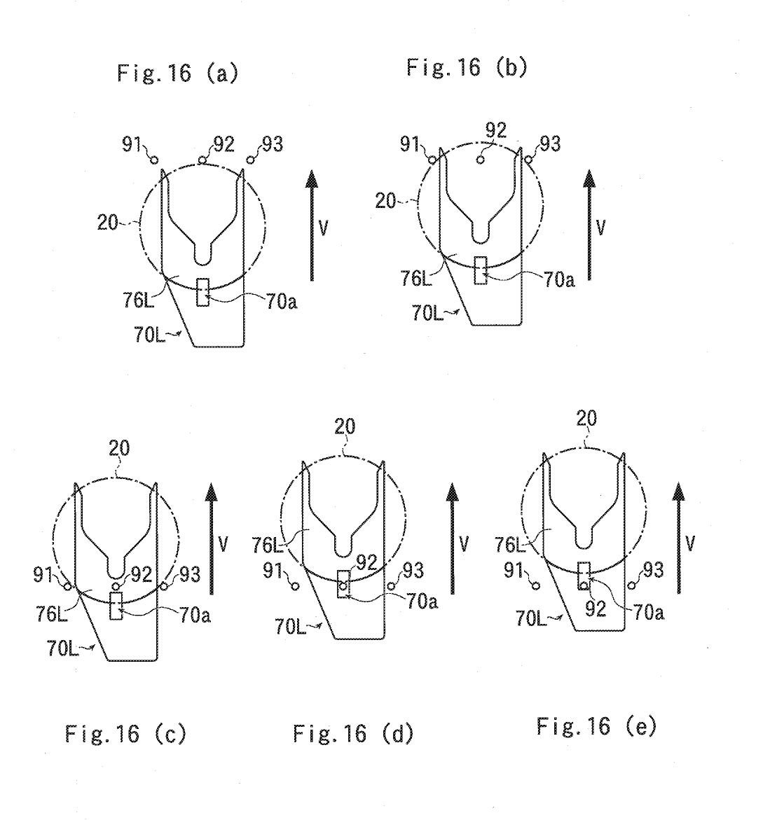

FIGS. 16(a), 16(b), 16(c), 16(d) and 16 (e) are explanatory views illustrating operations of detecting a position of a substrate in this embodiment.

In the following, with reference to FIGS. 16(a), 16(b), 16(c), 16(d) and 16(e), a description will be made of an example in which the substrate 20 is placed on the substrate mounting unit 76L of the left upper end effector 70L of the upper transfer device 1B, and is transferred.

After the substrate 20 is placed on the substrate mounting unit 76L of the left upper end effector 70L of the upper transfer device 1B, and the left upper transfer mechanism 7L is caused to operate to transfer the left upper end effector 70L in the substrate transfer direction V, the position sensor 92, located at the center, first detects the end edge portion of the central portion of the substrate 20 on the downstream side in the substrate transfer direction as illustrated in FIG. 16(a). Then, the results obtained with the position sensor 92 are sent to the controller 94, and are converted into a position coordinate in the controller 94, and then, the position coordinate is stored in the controller 94 (coordinate 1 of the detected position).

Then, as the transfer of the left upper end effector 70L continues, the position sensors 91 and 93, located on both sides, detect the end edge portions of both side portions of the substrate 20 on the downstream side in the substrate transfer direction as illustrated in FIG. 16 (b). The results of detection are sent to the controller 94, and are converted into position coordinates in the controller 94, and then, these position coordinates are stored in the controller 94 (coordinates 2 and 3 of the detected positions).

Furthermore, as the transfer of the left upper end effector 70L continues, the position sensors 91 and 93, located on both sides, detect the end edge portions of both side portions of the substrate 20 on the upstream side in the substrate transfer direction as illustrated in FIG. 16(c). The results of the detection are sent to the controller 94, and are converted into position coordinates in the controller 94, and then, these position coordinates are stored in the controller 94 (coordinates 4 and 5 of the detected positions).

In addition, as the transfer of the left upper end effector 70L continues, the position sensor 92, located at the center, detects the end edge portion of the central portion of the substrate 20 on the upstream side in the substrate transfer direction through the detection opening 70a as illustrated in FIG. 16(d). The results of detection are sent to the controller 94, and are converted into a position coordinate in the controller 94, and then, the position coordinate is stored in the controller 94 (coordinate 6 of the detected position).

Then, as the transfer of the left upper end effector 70L continues, the position sensor 92, located at the center, detects the end portion of the detection opening 70a of the left upper end effector 70L on the upstream side in the substrate transfer direction as illustrated in FIG. 16(e). The results of detection are sent to the controller 94, and are converted into a position coordinate in the controller 94, and then, the position coordinate is stored in the controller 94 (coordinate 7 of the detected position).

This coordinate 7 of the detected position is data for identifying the original coordinate for the coordinates 1 to 6 of the detected positions.

With these operations, the position coordinate of the substrate 20 at the time of passing through, for example, the position sensors 91 to 93 is calculated on the basis of the coordinates 1 to 7 of the detected positions stored in the controller 94. Data on the position coordinate of this substrate 20 is compared with data on the position coordinates stored in the controller 94 in advance, whereby calculation is made to obtain data concerning a difference (deviation of position coordinates) of the position coordinate of the substrate 20 being transferred, from an original path that this substrate 20 should take when being transferred to the substrate placement unit 20L.

Then, the drive source 95 is caused to operate on the basis of the calculated data on the deviation of the position coordinates, and the first turning drive shaft 15 is caused to drive to rotate the first turning drive member 31 at a predetermined small angle in a clockwise direction or counterclockwise direction with the rotating axis O as a center as illustrated in FIGS. 8 and 9, as described above, so that the substrate 20 placed on the substrate mounting unit 76L of the left upper end effector 70L of the upper transfer device 1B is positioned on the original path that the substrate 20 should take when being transferred.

Subsequently, by operating the left upper transfer mechanism. 7L of the upper transfer device 1B in accordance with a predetermined sequence, this substrate 20 is transferred and is placed on the substrate placement unit 20L within the processing chamber 81.

On the other hand, the right upper end effector 70R of the upper transfer device 1B also operates in substantially the same way as the left upper end effector 70L.

More specifically, in a similar way to the left upper end effector 70L, with the right upper end effector 70R, the substrate 20 is placed on the substrate mounting unit 76R and is transferred. The position sensors 91 to 93 detect each end edge portion of the substrate 20 and an end portion of the detection opening 70a on the upstream side in the substrate transfer direction; and the results of detection are sent to the controller 94. On the basis of data on each position coordinate converted by the controller 94, data on a position coordinate of this substrate 20 is calculated. The data thus obtained is compared with position coordinates stored in advance to calculate data on a deviation of the position coordinate of the substrate 20 being transferred, from an original path that this substrate 20 should take when being transferred to the substrate placement unit 20R.

Consequently, the drive source 96 is caused to operate on the basis of the calculated data on the deviation of the position coordinate. The second turning drive shaft 16 is caused to drive and rotate the second turning drive member 32 at a predetermined small angle in a clockwise direction or counterclockwise direction with the rotating axis O as a center as illustrated in FIGS. 8 and 9 for which description have been made above, so that the substrate 20 placed on the substrate mounting unit 76R of the right upper end effector 70R of the upper transfer device 1B is positioned on an original path that this substrate 20 should take when being transferred.

Subsequently, by operating the right upper transfer mechanism 7R of the upper transfer device 1B in accordance with a predetermined sequence, this substrate 20 is transferred and is placed on the substrate placement unit 20R within the processing chamber 82.

Description has been made by giving an example in which substrates 20 are placed on the substrate mounting units 76L and 76R of the left upper end effector 70L and the right upper end effector 70R of the upper transfer device 1B, and are transferred. However, in the case where substrates 20 are placed on the substrate mounting units 36L and 36R of the left upper end effector 30L and the right upper end effector 30R of the lower transfer device 1A and are transferred, substantially the same operations are performed to place a pair of substrates 20 on the substrate placement units 20L and 20R within the pair of processing chambers 81 and 82.

In the vacuum apparatus 10A according to this embodiment as described above, when substrates 20 are transferred and placed on the substrate placement units 20L and 20R, for example, within a pair of processing chambers 81 and 82, position coordinates of the substrates 20 calculated on the basis of the result of detection with the positioning sensors 91 to 93 are compared with position coordinates stored in the controller 94 in advance, and calculation is made to obtain a deviation of each position coordinate from the original path that the substrate 20 should take. Based on the calculated deviation of the position coordinate, substrates 20 on the substrate mounting units 76L and 76R of the left upper end effector 70L and the right upper end effector 70R of the upper transfer device 1B are positioned on the original path that these substrates 20 should take when being transferred. This makes it possible to correctly position the pair of substrates 20 transferred by the upper transfer device 1B on the substrate placement units 20L and 20R within the respective processing chambers 81 and 82. Thus, it is possible to improve throughput in carrying in or out the substrates 20 into or from each chamber.

Furthermore, according to this embodiment, it is possible to move a pair of substrates 20 placed on the substrate mounting units 76L and 76R of the left upper end effector 70L and the right upper end effector 70R of the upper transfer device 1B to position the substrates 20 on an original path that these substrates 20 should take, which makes it possible to rapidly place the pair of substrates 20 at correct positions as compared with a conventional system, which cannot correct the positional deviations for a pair of substrates simultaneously.

On the other hand, as understood from the above descriptions, the effects described above can be obtained in the case where substrates 20 are placed on the substrate mounting units 36L and 36R of the left upper end effector 30L and the right upper end effector 30R of the lower transfer device 1A having substantially the same configuration as the upper transfer device 1B; and the substrates 20 are transferred and placed.

It is noted that the vacuum apparatus according to the present invention is not limited to the embodiment described above, and various modifications are possible.

For example, the number of or the arrangement of the transfer object detection sensors that detect the position of a transfer object is not limited to three position sensors 91 to 93 as described above, and it may be possible to employ various number of sensors with various arrangements. Furthermore, as for the method of calculating position coordinates of a transfer object, it may be possible to employ various methods.

In addition, in the embodiment described above, position coordinates are calculated for each of the substrates 20, and then, these substrates 20 are positioned on an original path that each of these substrates 20 should take when being transferred. However, the present invention is not limited to such a structural arrangement, and it may be possible to employ a structural arrangement in which each substrate 20 is transferred to the vicinity of the substrate placement unit 20L, 20R, and then, the substrate 20 is moved to place it on the substrate placement unit 20L, 20R.

### EXPLANATION OF REFERENCE NUMERALS

1 transfer device
1A lower transfer device (first transfer device)
1B upper transfer device (second transfer device)
2L left lower transfer mechanism (first transfer mechanism)
2R right lower transfer mechanism (second transfer mechanism)
3a first left lower parallel crank mechanism
3b second left lower parallel crank mechanism
4a first right lower parallel crank mechanism
4b second right lower parallel crank mechanism
5a first left upper parallel crank mechanism
5b second left upper parallel crank mechanism
6a first right upper parallel crank mechanism
6b second right upper parallel crank mechanism
7L left upper transfer mechanism (third transfer mechanism)
7R right upper transfer mechanism (fourth transfer mechanism)
10 vacuum apparatus
11 first extension/contraction drive shaft
12 second extension/contraction drive shaft
13 third extension/contraction drive shaft
14 fourth extension/contraction drive shaft
15 first turning drive shaft
16 second turning drive shaft
20 substrate (transfer object)
20L, 20R substrate placement unit (transfer object placement unit)
31 first turning drive member
31a connecting member
32 second turning drive member
32a connecting member
80 transfer chamber (vacuum chamber)
81, 82, 83, 84, 87, 88 processing chamber
O rotating axis
V substrate transfer direction (transfer object transfer direction)

1. A transfer device, comprising:
first and second extension/contraction drive shafts for driving extension and contraction of first and second transfer mechanisms, the first and second extension/contraction drive shafts being disposed concentrically about a predetermined rotating axis as a center and each being provided in an independently rotatable manner in a horizontal plane; and
first and second turning drive shafts for turning the first and second transfer mechanisms, the first and second turning drive shafts being disposed concentrically about the first and second extension/contraction drive shafts,
wherein the first transfer mechanism is configured to be driven to extend and contract by the first extension/contraction drive shaft so as to transfer a first transfer unit along a transfer object transfer direction, and the second transfer mechanism is configured to be driven to extend and contract by the second extension/contraction drive shaft so as to transfer a second transfer unit along the transfer object transfer direction,
wherein the first and second transfer mechanisms have first and second turning drive members that are driven by the first and second turning drive shafts, respectively, and turn the first and second transfer mechanisms, respectively, about the rotating axis as a center, and
wherein the first transfer mechanism and the second transfer mechanism are disposed opposite to each other in the transfer object transfer direction with the rotating axis in between.

2. The transfer device according to claim 1, wherein
the first and second transfer mechanisms are disposed at a same height position.

3. A transfer device, comprising a first transfer device; and a second transfer device,
wherein the first transfer device comprises:
first and second extension/contraction drive shafts for driving extension and contraction of first and second transfer mechanisms, the first and second extension/contraction drive shafts being disposed concentrically about a predetermined rotating axis as a center, and each being provided in an independently rotatable manner in a horizontal plane, and
first and second turning drive shafts for turning the first and second transfer mechanisms, the first and second turning drive shafts being disposed concentrically about the first and second extension/contraction drive shafts,
wherein the first transfer mechanism is configured to be driven to extend and contract by the first extension/contraction drive shaft so as to transfer a first transfer unit along a transfer object transfer direction, and the second transfer mechanism is configured to be driven to extend and contract by the second extension/contraction drive shaft so as to transfer a second transfer unit along the transfer object transfer direction,
wherein the first and second transfer mechanisms have first and second turning drive members that are driven by the first and second turning drive shafts, respectively, and turn the first and second transfer mechanisms, respectively, about the rotating axis as a center, and
wherein the first transfer mechanism and the second transfer mechanism are disposed opposite to each other in the transfer object transfer direction with the rotating axis in between; and
wherein the second transfer device comprises third and fourth extension/contraction drive shafts for driving extension and contraction of third and fourth transfer mechanisms corresponding to the first and second transfer mechanisms, the third and forth transfer mechanisms being disposed concentrically about the rotating axis as a center and each being provided in an independently rotatable manner in a horizontal plane,
wherein the third and fourth transfer mechanisms are disposed at height positions different from the first and second transfer mechanisms and opposite to each other in the transfer object transfer direction with the rotating axis in between, and are configured to be driven to extend and contract by the third and fourth extension/contraction drive shafts, respectively, so as to transfer third and fourth transfer units, respectively, along the transfer object transfer direction, and have a linkage mechanism connected with each of the first and second turning drive members provided to the first and second transfer mechanisms, and are configured to turn the third and fourth transfer mechanisms by the linkage mechanism about the rotating axis as a center.

4. The transfer device according to claim 3, wherein
the first and second transfer mechanisms are disposed at a same height, and the third and fourth transfer mechanisms are disposed at a same height.

5. A vacuum apparatus, comprising:
a vacuum chamber; and
a transfer device provided in the vacuum chamber,
wherein the transfer device comprises:
first and second extension/contraction drive shafts for driving extension and contraction of first and second transfer mechanisms, the first and second extension/contraction drive shafts being disposed concentrically about a predetermined rotating axis as a center and each being provided in an independently rotatable manner in a horizontal plane, and
first and second turning drive shafts for turning the first and second transfer mechanisms, the first and second turning drive shafts being disposed concentrically about the first and second extension/contraction drive shafts,
wherein the first transfer mechanism is configured to be driven to extend and contract by the first extension/contraction drive shaft so as to transfer a first transfer unit along a transfer object transfer direction, and the second transfer mechanism is configured to be driven to extend and contract by the second extension/contraction drive shaft so as to transfer a second transfer unit along the transfer object transfer direction,
wherein the first and second transfer mechanisms have first and second turning drive members that are driven by the first and second turning drive shafts, respectively, and turn the first and second transfer mechanisms, respectively, about the rotating axis as a center, and
wherein the first transfer mechanism and the second transfer mechanism are disposed opposite to each other in the transfer object transfer direction with the rotating axis in between.

6. The vacuum apparatus according to claim 5, further comprising:
a pair of transfer object detection sensors for detecting a pair of transfer objects transferred by the first and second transfer mechanisms, respectively, the pair of transfer object detection sensors being made of a plurality of sensors provided in the vacuum chamber; and
a controller that controls movement of each of the first and second turning drive shafts so that the pair of transfer objects are placed on a pair of transfer object placement units based on a result of detection by the pair of transfer object detection sensors.
